(19) United States
(12) Patent Application Publication
(10) Pub. No.: US 2026/0066001 A1
(43) Pub. Date: Mar. 5, 2026

(54) CONFIGURABLE INPUT AND OUTPUT BLOCKS FOR VECTOR-BY-MATRIX MULTIPLICATION ARRAY

(71) Applicant: Silicon Storage Technology, Inc., San Jose, CA (US)

(72) Inventors: Hieu Van Tran, San Jose, CA (US); Hoa Vu, Milpitas, CA (US); Andrew Kunil Choe, San Jose, CA (US); Thuan Vu, San Jose, CA (US); Stanley Hong, San Jose, CA (US); Stephen Trinh, San Jose, CA (US)

(21) Appl. No.: 18/943,886

(22) Filed: Nov. 11, 2024

Related U.S. Application Data
(60) Provisional application No. 63/688,291, filed on Aug. 28, 2024.

(51) Int. Cl. G11C 16/26; G11C 16/30

(52) U.S. Cl. CPC G11C 16/26; G11C 16/30

(57) ABSTRACT

In one example, a system comprises a vector-by-matrix multiplication array comprising non-volatile memory cells arranged into rows and columns; and an output block coupled to the vector-by-matrix multiplication array to receive current from the columns of the array, the output block comprising a current-to-voltage converter to receive current from one or two columns and convert the current into a voltage, the current-to-voltage converter comprising one or more variable resistors configurable to adjust the range of the voltage; and an analog-to-digital converter to convert the voltage into digital bits.

### PRIORITY CLAIM

This application claims priority to U.S. Provisional Patent Application No. 63/688,291, titled “Configurable Input and Output Blocks for Vector-By-Matrix Multiplication Array,” which is incorporated by reference herein.

### FIELD OF THE INVENTION

Numerous examples are disclosed of configurable input and output blocks and associated methods for a neural network array.

### BACKGROUND OF THE INVENTION

Artificial neural networks mimic biological neural networks (the central nervous systems of animals, in particular the brain) and are used to estimate or approximate functions that can depend on a large number of inputs and are generally unknown. Artificial neural networks generally include layers of interconnected “neurons” which exchange messages between each other.

FIG. 1 illustrates an artificial neural network, where the circles represent the inputs or layers of neurons. The connections (called synapses) are represented by arrows and have numeric weights that can be tuned based on experience. This makes neural networks adaptive to inputs and capable of learning. Typically, neural networks include a layer of multiple inputs. There are typically one or more intermediate layers of neurons, and an output layer of neurons that provide the output of the neural network. The neurons at each level individually or collectively make a decision based on the received data from the synapses.

One of the major challenges in the development of artificial neural networks for high-performance information processing is a lack of adequate hardware technology. Indeed, practical neural networks rely on a very large number of synapses, enabling high connectivity between neurons, i.e., a very high computational parallelism. In principle, such complexity can be achieved with digital supercomputers or graphics processing unit clusters. However, in addition to high cost, these approaches also suffer from mediocre energy efficiency as compared to biological networks, which consume much less energy primarily because they perform low-precision analog computation. CMOS analog circuits have been used for artificial neural networks, but most CMOS-implemented synapses have been too bulky given the high number of neurons and synapses.

Applicant previously disclosed an artificial (analog) neural network that utilizes one or more non-volatile memory arrays as the synapses in U.S. Patent Application Publication 2017/0337466A1, which is incorporated by reference. The non-volatile memory arrays operate as an analog neural memory and comprise non-volatile memory cells arranged in rows and columns. The neural network includes a first plurality of synapses configured to receive a first plurality of inputs and to generate therefrom a first plurality of outputs, and a first plurality of neurons configured to receive the first plurality of outputs. The first plurality of synapses includes a plurality of memory cells, wherein each of the memory cells includes spaced apart source and drain regions formed in a semiconductor substrate with a channel region extending there between, a floating gate disposed over and insulated from a first portion of the channel region and a non-floating gate disposed over and insulated from a second portion of the channel region. Each of the plurality of memory cells store a weight value corresponding to a number of electrons on the floating gate. The plurality of memory cells multiply the first plurality of inputs by the stored weight values to generate the first plurality of outputs.

### Non-Volatile Memory Cells

Non-volatile memories are well known. For example, U.S. Pat. No. 5,029,130 (“the '130 patent”), which is incorporated herein by reference, discloses an array of split gate non-volatile memory cells, which are a type of flash memory cells. Such a memory cell 210 is shown in FIG. 2. Each memory cell 210 includes source region 14 and drain region 16 formed in semiconductor substrate 12, with channel region 18 there between. Floating gate 20 is formed over and insulated from (and controls the conductivity of) a first portion of the channel region 18, and over a portion of the source region 14. Word line terminal 22 (which is typically coupled to a word line) has a first portion that is disposed over and insulated from (and controls the conductivity of) a second portion of the channel region 18, and a second portion that extends up and over the floating gate 20. The floating gate 20 and word line terminal 22 are insulated from the substrate 12 by a gate oxide. Bitline 24 is coupled to drain region 16.

Memory cell 210 is erased (where electrons are removed from the floating gate) by placing a high positive voltage on the word line terminal 22, which causes electrons on the floating gate 20 to tunnel through the intermediate insulation from the floating gate 20 to the word line terminal 22 via Fowler-Nordheim (FN) tunneling.

Memory cell 210 is programmed by source side injection (SSI) with hot electrons (where electrons are placed on the floating gate) by placing a positive voltage on the word line terminal 22, and a positive voltage on the source region 14. Electron current will flow from the drain region 16 towards the source region 14. The electrons will accelerate and become heated when they reach the gap between the word line terminal 22 and the floating gate 20. Some of the heated electrons will be injected through the gate oxide onto the floating gate 20 due to the attractive electrostatic force from the floating gate 20.

Memory cell 210 is read by placing positive read voltages on the drain region 16 and word line terminal 22 (which turns on the portion of the channel region 18 under the word line terminal). If the floating gate 20 is positively charged (i.e., erased of electrons), then the portion of the channel region 18 under the floating gate 20 is turned on as well, and current will flow across the channel region 18, which is sensed as the erased or “1” state. If the floating gate 20 is negatively charged (i.e., programmed with electrons), then the portion of the channel region under the floating gate 20 is mostly or entirely turned off, and current will not flow (or there will be little flow) across the channel region 18, which is sensed as the programmed or “0” state.

Table No. 1 depicts typical voltage and current ranges that can be applied to the terminals of memory cell 210 for performing read, erase, and program operations:

TABLE NO 1
Operation of Flash Memory Cell 210 of FIG. 2

| | | |
|---|---|---|
| WL | BL | SL |

| | | | | | | |
|---|---|---|---|---|---|---|
| Read | 2-3 | V | 0.6-2 | V | 0 | V |
| Erase | ~11-13 | V | 0 | V | 0 | V |
| Program | 1-2 | V | 10.5-3 | μA | 9-10 | V |

Other split gate memory cell configurations, which are other types of flash memory cells, are known. For example, FIG. 3 depicts a four-gate memory cell 310 comprising source region 14, drain region 16, floating gate 20 over a first portion of channel region 18, a select gate 22 (typically coupled to a word line, WL) over a second portion of the channel region 18, a control gate 28 over the floating gate 20, and an erase gate 30 over the source region 14. This configuration is described in U.S. Pat. No. 6,747,310, which is incorporated herein by reference for all purposes. Here, all gates are non-floating gates except floating gate 20, meaning that they are electrically connected or connectable to a voltage source. Programming is performed by heated electrons from the channel region 18 injecting themselves onto the floating gate 20. Erasing is performed by electrons tunneling from the floating gate 20 to the erase gate 30.

Table No. 2 depicts typical voltage and current ranges that can be applied to the terminals of memory cell 310 for performing read, erase, and program operations:

TABLE NO 2
Operation of Flash Memory Cell 310 of FIG. 3

| | WL/SG | | BL | | CG | | EG | | SL | |
|---|---|---|---|---|---|---|---|---|---|---|
| Read | 1.0-2 | V | 0.6-2 | V | 0-2.6 | V | 0-2.6 | V | 0 | V |
| Erase | −0.5 V/0 V | | 0 | V | 0 V/−8 V | | 8-12 | V | 0 | V |
| Program | 1 | V | 0.1-1 | μA | 8-11 | V | 4.5-9 | V | 4.5-5 | V |

FIG. 4 depicts a three-gate memory cell 410, which is another type of flash memory cell. Memory cell 410 is identical to the memory cell 310 of FIG. 3 except that memory cell 410 does not have a separate control gate. The erase operation (whereby erasing occurs through use of the erase gate) and read operation are similar to that of the FIG. 3 except there is no control gate bias applied. The programming operation also is done without the control gate bias, and as a result, a higher voltage is applied on the source line during a program operation to compensate for a lack of control gate bias.

Table No. 3 depicts typical voltage and current ranges that can be applied to the terminals of memory cell 410 for performing read, erase, and program operations:

TABLE NO 3
Operation of Flash Memory Cell 410 of FIG. 4

| | | | |
|---|---|---|---|
| WL/SG | BL | EG | SL |

| | | | | | | | | |
|---|---|---|---|---|---|---|---|---|
| Read | 0.7-2.2 | V | 0.6-2 | V | 0-2.6 | V | 0 | V |

| | | | | | | | |
|---|---|---|---|---|---|---|---|
| Erase | −0.5 V/0 V | 0 | V | 11.5 | V | 0 | V |

| | | | | | | | | |
|---|---|---|---|---|---|---|---|---|
| Program | 1 | V | 0.2-3 | μA | 4.5 | V | 7-9 | V |

FIG. 5 depicts stacked gate memory cell 510, which is another type of flash memory cell. Memory cell 510 is similar to memory cell 210 of FIG. 2, except that floating gate 20 extends over the entire channel region 18, and control gate 22 (which here will be coupled to a word line) extends over floating gate 20, separated by an insulating layer (not shown). The erase is done by FN tunneling of electrons from FG to substrate, programming is by channel hot electron (CHE) injection at region between the channel 18 and the drain region 16, by the electrons flowing from the source region 14 towards to drain region 16 and read operation which is similar to that for memory cell 210 with a higher control gate voltage.

Table No. 4 depicts typical voltage ranges that can be applied to the terminals of memory cell 510 and substrate 12 for performing read, erase, and program operations:

TABLE NO 4
Operation of Flash Memory Cell 510 of FIG. 5

| | CG | | BL | | SL | Substrate |
|---|---|---|---|---|---|---|
| Read | 2-5 | V | 0.6-2 | V | 0 V | 0 V |
| Erase | −8 to −10 V/0 V | | FLT | | FLT | 8-10 V/15-20 V |
| Program | 8-12 | V | 3-5 | V | 0 V | 0 V |

The methods and means described herein may apply to other non-volatile memory technologies such as FINFET split gate flash or stack gate flash memory, NAND flash, SONOS (silicon-oxide-nitride-oxide-silicon, charge trap in nitride), MONOS (metal-oxide-nitride-oxide-silicon, metal charge trap in nitride), ReRAM (resistive ram), PCM (phase change memory), MRAM (magnetic ram), FeRAM (ferroelectric ram), CT (charge trap) memory, CN (carbon-tube) memory, OTP (bi-level or multi-level one time programmable), and CeRAM (correlated electron ram), without limitation.

In order to utilize the memory arrays comprising one of the types of non-volatile memory cells described above in an artificial neural network, two modifications are made. First, the lines are configured so that each memory cell can be individually programmed, erased, and read without adversely affecting the memory state of other memory cells in the array, as further explained below. Second, continuous (analog) programming of the memory cells is provided.

Specifically, the memory state (i.e., charge on the floating gate) of each memory cell in the array can be continuously changed from a fully erased state to a fully programmed state, and vice-versa, independently and with minimal disturbance of other memory cells. This means the cell storage is effectively analog or at the very least can store one of many discrete values (such as 16 or 64 different values), which allows for very precise and individual tuning of all the memory cells in the memory array, and which makes the memory array ideal for storing and making fine tuning adjustments to the synapsis weights of the neural network.

### Neural Networks Employing Non-Volatile Memory Cell Arrays

FIG. 6 conceptually illustrates a non-limiting example of a neural network utilizing a non-volatile memory array of the present examples. This example uses the non-volatile memory array neural network for a facial recognition application, but any other appropriate application could be implemented using a non-volatile memory array based neural network.

S0 is the input layer, which for this example is a 32×32 pixel RGB image with 5 bit precision (i.e. three 32×32 pixel arrays, one for each color R, G and B, each pixel being 5 bit precision). The synapses CB1 going from input layer S0 to layer C1 apply different sets of weights in some instances and shared weights in other instances and scan the input image with 3×3 pixel overlapping filters (kernel), shifting the filter by 1 pixel (or more than 1 pixel as dictated by the model). Specifically, values for 9 pixels in a 3×3 portion of the image (i.e., referred to as a filter or kernel) are provided to the synapses CB1, where these 9 input values are multiplied by the appropriate weights and, after summing the outputs of that multiplication, a single output value is determined and provided by a first synapse of CB1 for generating a pixel of one of the feature maps of layer C1. The 3×3 filter is then shifted one pixel to the right within input layer S0 (i.e., adding the column of three pixels on the right, and dropping the column of three pixels on the left), whereby the 9 pixel values in this newly positioned filter are provided to the synapses CB1, where they are multiplied by the same weights and a second single output value is determined by the associated synapse. This process is continued until the 3×3 filter scans across the entire 32×32 pixel image of input layer S0, for all three colors and for all bits (precision values). The process is then repeated using different sets of weights to generate a different feature map of layer C1, until all the features maps of layer C1 have been calculated.

In layer C1, in the present example, there are 16 feature maps, with 30×30 pixels each. Each pixel is a new feature pixel extracted from multiplying the inputs and kernel, and therefore each feature map is a two dimensional array, and thus in this example layer C1 constitutes 16 layers of two dimensional arrays (keeping in mind that the layers and arrays referenced herein are logical relationships and may not be physical relationships—i.e., the arrays might not be oriented in physical two dimensional arrays). Each of the 16 feature maps in layer C1 is generated by one of sixteen different sets of synapse weights applied to the filter scans. The C1 feature maps could all be directed to different aspects of the same image feature, such as boundary identification. For example, the first map (generated using a first weight set, shared for all scans used to generate this first map) could identify circular edges, the second map (generated using a second weight set different from the first weight set) could identify rectangular edges, or the aspect ratio of certain features, and so on.

An activation function P1 (pooling) is applied before going from layer C1 to layer S1, which pools values from consecutive, non-overlapping 2×2 regions in each feature map. The purpose of the pooling function P1 is to average out the nearby location (or a max function can also be used), to reduce the dependence of the edge location for example and to reduce the data size before going to the next stage. At layer S1, there are 16 15×15 feature maps (i.e., sixteen different arrays of 15×15 pixels each). The synapses CB2 going from layer S1 to layer C2 scan maps in layer S1 with 4×4 filters, with a filter shift of 1 pixel. At layer C2, there are 22 12×12 feature maps. An activation function P2 (pooling) is applied before going from layer C2 to layer S2, which pools values from consecutive non-overlapping 2×2 regions in each feature map. At layer S2, there are 22 6×6 feature maps. An activation function (pooling) is applied at the synapses CB3 going from layer S2 to layer C3, where every neuron in layer C3 connects to every map in layer S2 via a respective synapse of CB3. At layer C3, there are 64 neurons. The synapses CB4 going from layer C3 to the output layer S3 fully connects C3 to S3, i.e. every neuron in layer C3 is connected to every neuron in layer S3. The output at S3 includes 10 neurons, where the highest output neuron determines the class. This output could, for example, be indicative of an identification or classification of the contents of the original image.

Each layer of synapses is implemented using an array, or a portion of an array, of non-volatile memory cells.

FIG. 7 is a block diagram of an array that can be used for that purpose. Vector-by-matrix multiplication (VMM) array 32 includes non-volatile memory cells and is utilized as the synapses (such as CB1, CB2, CB3, and CB4 in FIG. 6) between one layer and the next layer. Specifically, VMM array 32 includes an array of non-volatile memory cells 33, erase gate and word line gate decoder 34, control gate decoder 35, bit line decoder 36 and source line decoder 37, which decode the respective inputs for the non-volatile memory cell array 33. Input to VMM array 32 can be from the erase gate and wordline gate decoder 34 or from the control gate decoder 35. Source line decoder 37 in this example also decodes the output of the non-volatile memory cell array 33. Alternatively, bit line decoder 36 can decode the output of the non-volatile memory cell array 33.

Non-volatile memory cell array 33 serves two purposes. First, it stores the weights that will be used by the VMM array 32. Second, the non-volatile memory cell array 33 effectively multiplies the inputs by the weights stored in the non-volatile memory cell array 33 and adds them up per output line (source line or bit line) to produce the output, which will be the input to the next layer or input to the final layer. By performing the multiplication and addition function, the non-volatile memory cell array 33 negates the utilization of separate multiplication and addition logic circuits and is also power efficient due to its in-situ memory computation.

The output of non-volatile memory cell array 33 is supplied to a differential summer (such as a summing op-amp or a summing current mirror) 38, which sums up the outputs of the non-volatile memory cell array 33 to create a single value for that convolution. The differential summer 38 is arranged to perform summation of positive weight and negative weight.

The summed-up output values of differential summer 38 are then supplied to an activation function block 39, which rectifies the output. The activation function block 39 may provide sigmoid, tanh, or ReLU functions. The rectified output values of activation function block 39 become an element of a feature map as the next layer (e.g. C1 in FIG. 6), and are then applied to the next synapse to produce the next feature map layer or final layer. Therefore, in this example, non-volatile memory cell array 33 constitutes a plurality of synapses (which receive their inputs from the prior layer of neurons or from an input layer such as an image database), and summing op-amp 38 and activation function block 39 constitute a plurality of neurons.

The input to VMM array 32 in FIG. 7 (WLx, EGx, CGx, and optionally BLx and SLx) can be analog level, binary level, or digital bits (in which case a DAC is provided to convert digital bits to appropriate input analog level) and the output can be analog level, binary level, or digital bits (in which case an output ADC is provided to convert output analog level into digital bits).

FIG. 8 is a block diagram depicting the usage of numerous layers of VMM arrays 32, here labeled as VMM arrays 32a, 32b, 32c, 32d, and 32c. As shown in FIG. 8, the input, denoted Inputx, is converted from digital to analog by a digital-to-analog converter 31 and provided to input VMM array 32a. The converted analog inputs could be voltage or current. The input D/A conversion for the first layer could be done by using a function or a LUT (look up table) that maps the inputs Inputx to appropriate analog levels for the matrix multiplier of input VMM array 32a. The input conversion could also be done by an analog to analog (A/A) converter to convert an external analog input to a mapped analog input to the input VMM array 32a.

The output generated by input VMM array 32a is provided as an input to the next VMM array (hidden level 1) 32b, which in turn generates an output that is provided as an input to the next VMM array (hidden level 2) 32c, and so on. The various layers of VMM array 32 function as different layers of synapses and neurons of a convolutional neural network (CNN). Each VMM array 32a, 32b, 32c, 32d, and 32e can be a stand-alone, physical non-volatile memory array, or multiple VMM arrays could utilize different portions of the same physical non-volatile memory array, or multiple VMM arrays could utilize overlapping portions of the same physical non-volatile memory array. The example shown in FIG. 8 contains five layers (32a,32b,32c,32d,32c): one input layer (32a), two hidden layers (32b,32c), and two fully connected layers (32d,32e). One of ordinary skill in the art will appreciate that this is merely an example and that a system instead could comprise more than two hidden layers and more than two fully connected layers.

### Vector-by-Matrix Multiplication (VMM) Arrays

FIG. 9 depicts neuron VMM array 900, which is particularly suited for memory cells 310 as shown in FIG. 3 and is utilized as the synapses and parts of neurons between an input layer and the next layer. VMM array 900 comprises memory array 901 of non-volatile memory cells and reference array 902 (at the top of the array) of non-volatile reference memory cells. Alternatively, another reference array can be placed at the bottom.

In VMM array 900, control gate lines, such as control gate line 903, run in a vertical direction (hence reference array 902 in the row direction is orthogonal to control gate line 903), and erase gate lines, such as erase gate line 904, run in a horizontal direction. Here, the inputs to VMM array 900 are provided on the control gate lines (CG0, CG1, CG2, CG3), and the output of VMM array 900 emerges on the source lines (SL0, SL1). In one example, even rows are used, and in another example, odd rows are used. The current placed on each source line (SL0, SL1, respectively) performs a summing function of all the currents from the memory cells connected to that particular source line.

As described herein for neural networks, the non-volatile memory cells of VMM array 900, i.e., the memory cells 310 of VMM array 900, may be configured to operate in a sub-threshold region.

The non-volatile reference memory cells and the non-volatile memory cells described herein are biased in weak inversion (sub threshold region):

$$Ids = Io * {e}^{( V g - V th ) / n V t} = w * Io * {e}^{( V g ) / n V t} ,$$

$$where w = {e}^{( - V th ) / n V t}$$

where Ids is the drain to source current; Vg is gate voltage on the memory cell; Vth is threshold voltage of the memory cell; Vt is thermal voltage=k*T/q with k being the Boltzmann constant, T the temperature in Kelvin, and q the electronic charge; n is a slope factor=1+(Cdep/Cox) with Cdep=capacitance of the depletion layer, and Cox capacitance of the gate oxide layer; Io is the memory cell current at gate voltage equal to threshold voltage, Io is proportional to (Wt/L)*u*Cox*(n−1)*Vt² where u is carrier mobility and Wt and L are width and length, respectively, of the memory cell.

For an I-to-V log converter using a memory cell (such as a reference memory cell or a peripheral memory cell) or a transistor to convert input current into an input voltage:

$$V g = n * V t * log [ Ids / wp * Io ]$$

where, wp is w of a reference or peripheral memory cell.

For a memory array used as a vector matrix multiplier VMM array with the current input, the output current is:

$$Iout = wa * Io * {e}^{( V g ) / n V t} , namely$$

$$Iout = ( wa / wp ) * Iin = W * Iin$$

$$W = {e}^{( V thp - V tha ) / n V t}$$

Here, wa=w of each memory cell in the memory array.
Vthp is effective threshold voltage of the peripheral memory cell and Vtha is effective threshold voltage of the main (data) memory cell. Note that the threshold voltage of a transistor is a function of substrate body bias voltage and the substrate body bias voltage, denoted Vsb, can be modulated to compensate for various conditions, on such temperature. The threshold voltage Vth can be expressed as:

$$V th = V th 0 + gamma ( SQRT \vert V sb - 2 * φ F ) - SQRT \vert 2 * φ F \vert )$$

where Vth0 is threshold voltage with zero substrate bias, φF is a surface potential, and gamma is a body effect parameter.

A wordline or control gate can be used as the input for the memory cell for the input voltage.

Alternatively, the flash memory cells of VMM arrays described herein can be configured to operate in the linear region:

$$Ids = beta * ( V gs - V th ) * V ds ; beta = u * Cox * Wt / L$$

$$W = α ( V gs - V th )$$

meaning weight W in the linear region is proportional to (Vgs−Vth)

A wordline or control gate or bitline or sourceline can be used as the input for the memory cell operated in the linear region. The bitline or sourceline can be used as the output for the memory cell.

For an I-to-V linear converter, a memory cell (such as a reference memory cell or a peripheral memory cell) or a transistor operating in the linear region can be used to linearly convert an input/output current into an input/output voltage.

Alternatively, the memory cells of VMM arrays described herein can be configured to operate in the saturation region:

$$Ids = 1 / 2 * beta * {( V gs - V th )}^{2} ; beta = u * Cox * Wt / L$$

Wα(Vgs−Vth)², meaning weight W is proportional to (Vgs−Vth)²

A wordline, control gate, or erase gate can be used as the input for the memory cell operated in the saturation region. The bitline or sourceline can be used as the output for the output neuron.

Alternatively, the memory cells of VMM arrays described herein can be used in all regions or a combination thereof (sub threshold, linear, or saturation) for each layer or multi layers of a neural network.

Other examples for VMM array 32 of FIG. 7 are described in U.S. Pat. No. 10,748,630, which is incorporated by reference herein. As described in that application. a sourceline or a bitline can be used as the neuron output (current summation output).

FIG. 10 depicts neuron VMM array 1000, which is particularly suited for memory cells 210 as shown in FIG. 2 and is utilized as the synapses between an input layer and the next layer. VMM array 1000 comprises a memory array 1003 of non-volatile memory cells, reference array 1001 of first non-volatile reference memory cells, and reference array 1002 of second non-volatile reference memory cells. Reference arrays 1001 and 1002, arranged in the column direction of the array, serve to convert current inputs flowing into terminals BLR0, BLR1, BLR2, and BLR3 into voltage inputs WL0, WL1, WL2, and WL3. In effect, the first and second non-volatile reference memory cells are diode-connected through multiplexors 1014 (partially depicted) with current inputs flowing into them. The reference cells are tuned (e.g., programmed) to target reference levels. The target reference levels are provided by a reference mini-array matrix (not shown).

Memory array 1003 serves two purposes. First, it stores the weights that will be used by the VMM array 1000 on respective memory cells thereof. Second, memory array 1003 effectively multiplies the inputs (i.e. current inputs provided in terminals BLR0, BLR1, BLR2, and BLR3, which reference arrays 1001 and 1002 convert into the input voltages to supply to wordlines WL0, WL1, WL2, and WL3) by the weights stored in the memory array 1003 and then adds all the results (memory cell currents) to produce the output on the respective bit lines (BL0-BLN), which will be the input to the next layer or input to the final layer. By performing the multiplication and addition function, memory array 1003 negates the utilization of separate multiplication and addition logic circuits and is also power efficient. Here, the voltage inputs are provided on the word lines WL0, WL1, WL2, and WL3, and the output emerges on the respective bit lines BL0-BLN during a read (inference) operation. The current placed on each of the bit lines BL0-BLN performs a summing function of the currents from all non-volatile memory cells connected to that particular bitline.

Table No. 5 depicts operating voltages and currents for VMM array 1000. The columns in the table indicate the voltages placed on word lines for selected cells, word lines for unselected cells, bit lines for selected cells, bit lines for unselected cells, source lines for selected cells, and source lines for unselected cells. The rows indicate the operations of read, erase, and program.

TABLE NO 5
Operation of VMM Array 1000 of FIG. 10:

| | WL | | WL -unsel | BL | | BL -unsel | SL | | SL -unsel | |
|---|---|---|---|---|---|---|---|---|---|---|
| Read | 1-3.5 | V | −0.5 V/0 V | 0.6-2 | V (Ineuron) | 0.6 V-2 V/0 V | 0 | V | 0 | V |
| Erase | ~5-13 | V | 0 V | 0 | V | 0 V | 0 | V | 0 | V |
| Program | 1-2 | V | −0.5 V/0 V | 0.1-3 | uA | Vinh ~2.5 V | 4-10 | V | 0-1 | V/FLT |

FIG. 11 depicts neuron VMM array 1100, which is particularly suited for memory cells 210 as shown in FIG. 2 and is utilized as the synapses and parts of neurons between an input layer and the next layer. VMM array 1100 comprises a memory array 1103 of non-volatile memory cells, reference array 1101 of first non-volatile reference memory cells, and reference array 1102 of second non-volatile reference memory cells. Reference arrays 1101 and 1102 run in row direction of the VMM array 1100. VMM array is similar to VMM 1000 except that in VMM array 1100, the word lines run in the vertical direction. Here, the inputs are provided on the word lines (WLA0, WLB0, WLA1, WLB2, WLA2, WLB2, WLA3, WLB3), and the output emerges on the source line (SL0, SL1) during a read operation. The current placed on each source line performs a summing function of all the currents from the memory cells connected to that particular source line.

Table No. 6 depicts operating voltages and currents for VMM array 1100. The columns in the table indicate the voltages placed on word lines for selected cells, word lines for unselected cells, bit lines for selected cells, bit lines for unselected cells, source lines for selected cells, and source lines for unselected cells. The rows indicate the operations of read, erase, and program.

TABLE NO 6
Operation of VMM Array 1100 of FIG. 11

| | WL | | WL -unsel | BL | | BL -unsel | SL | | SL -unsel | |
|---|---|---|---|---|---|---|---|---|---|---|
| Read | 1-3.5 | V | −0.5 V/0 V | 0.6-2 | V | 0.6 V-2 V/0 V | ~0.3-1 | V | 0 | V |
| | | | | | | | (Ineuron) | | | |
| Erase | ~5-13 | V | 0 V | 0 | V | 0 V | 0 | V | SL-inhibit (~4- | |
| | | | | | | | | | 8 V) | |
| Program | 1-2 | V | −0.5 V/0 V | 0.1-3 | uA | Vinh ~2.5 V | 4-10 | V | 0-1 | V/FLT |

FIG. 12 depicts neuron VMM array 1200, which is particularly suited for memory cells 310 as shown in FIG. 3 and is utilized as the synapses and parts of neurons between an input layer and the next layer. VMM array 1200 comprises a memory array 1203 of non-volatile memory cells, reference array 1201 of first non-volatile reference memory cells, and reference array 1202 of second non-volatile reference memory cells. Reference arrays 1201 and 1202 serve to convert current inputs flowing into terminals BLR0, BLR1, BLR2, and BLR3 into voltage inputs CG0, CG1, CG2, and CG3. In effect, the first and second non-volatile reference memory cells are diode-connected through multiplexors 1212 (partially shown) with current inputs flowing into them through BLR0, BLR1, BLR2, and BLR3. Multiplexors 1212 each include a respective multiplexor 1205 and a cascoding transistor 1204 to ensure a constant voltage on the bitline (such as BLR0) of each of the first and second non-volatile reference memory cells during a read operation. The reference cells are tuned to target reference levels.

Memory array 1203 serves two purposes. First, it stores the weights that will be used by the VMM array 1200. Second, memory array 1203 effectively multiplies the inputs (current inputs provided to terminals BLR0, BLR1, BLR2, and BLR3, for which reference arrays 1201 and 1202 convert these current inputs into the input voltages to supply to the control gates (CG0, CG1, CG2, and CG3) by the weights stored in the memory array and then add all the results (cell currents) to produce the output, which appears on BL0-BLN, and will be the input to the next layer or input to the final layer. By performing the multiplication and addition function, the memory array negates the utilization of separate multiplication and addition logic circuits and is also power efficient. Here, the inputs are provided on the control gate lines (CG0, CG1, CG2, and CG3), and the output emerges on the bit lines (BL0-BLN) during a read operation. The current placed on each bitline performs a summing function of all the currents from the memory cells connected to that particular bitline.

VMM array 1200 implements uni-directional tuning for non-volatile memory cells in memory array 1203. That is, each non-volatile memory cell is erased and then partially programmed until the desired charge on the floating gate is reached. If too much charge is placed on the floating gate (such that the wrong value is stored in the cell), the cell is erased and the sequence of partial programming operations starts over. As shown, two rows sharing the same erase gate (such as EG0 or EG1) are erased together (which is sometimes referred to as a page erase), and thereafter, each cell is partially programmed until the desired charge on the floating gate is reached.

Table No. 7 depicts operating voltages and currents for VMM array 1200. The columns in the table indicate the voltages placed on word lines for selected cells, word lines for unselected cells, bit lines for selected cells, bit lines for unselected cells, control gates for selected cells, control gates for unselected cells in the same sector as the selected cells, control gates for unselected cells in a different sector than the selected cells, erase gates for selected cells, erase gates for unselected cells, source lines for selected cells, and source lines for unselected cells. The rows indicate the operations of read, erase, and program.

TABLE NO 7
Operation of VMM Array 1200 of FIG. 12

| | | | | | | | | | | CG - | | | | | | | | | | | |
|---|---|---|---|---|---|---|---|---|---|---|---|---|---|---|---|---|---|---|---|---|---|
| | | | | | | | | | | unsel | | | | | | | | | | | |
| | | | WL - | | | BL - | | | | same | | CG - | | | | EG - | | | | SL - | |
| | WL | | unsel | BL | | unsel | | CG | | sector | | unsel | | EG | | unsel | | SL | | unsel | |
| Read | 1.0-2 | V | −0.5 V/0 V | 0.6-2 | V | 0 | V | 0-2.6 | V | 0-2.6 | V | 0-2.6 | V | 0-2.6 | V | 0-2.6 | V | 0 | V | 0 | V |
| | | | | (Ineuron) | | | | | | | | | | | | | | | | | |
| Erase | 0 | V | 0 V | 0 | V | 0 | V | 0 | V | 0-2.6 | V | 0-2.6 | V | 5-12 | V | 0-2.6 | V | 0 | V | 0 | V |

| | | | | | | | | | | | | | | | | | | | | |
|---|---|---|---|---|---|---|---|---|---|---|---|---|---|---|---|---|---|---|---|---|
| Program | 0.7-1 | V | −0.5 V/0 V | 0.1-1 | uA | Vinh | 4-11 | V | 0-2.6 | V | 0-2.6 | V | 4.5-5 | V | 0-2.6 | V | 4.5-5 | V | 0-1 | V |

(1-2 V)

FIG. 13 depicts neuron VMM array 1300, which is particularly suited for memory cells 310 as shown in FIG. 3 and is utilized as the synapses and parts of neurons between an input layer and the next layer. VMM array 1300 comprises a memory array 1303 of non-volatile memory cells, reference array 1301 or first non-volatile reference memory cells, and reference array 1302 of second non-volatile reference memory cells. EG lines EGR0, EG0, EG1 and EGR1 are run vertically while CG lines CG0, CG1, CG2 and CG3 and SL lines WL0, WL1, WL2 and WL3 are run horizontally. VMM array 1300 is similar to VMM array 1400, except that VMM array 1300 implements bi-directional tuning, where each individual cell can be completely erased, partially programmed, and partially erased to reach the desired amount of charge on the floating gate due to the use of separate EG lines. As shown, reference arrays 1301 and 1302 convert input current in the terminal BLR0, BLR1, BLR2, and BLR3 into control gate voltages CG0, CG1, CG2, and CG3 (through the action of diode-connected reference cells through multiplexors 1314) to be applied to the memory cells in the row direction. The current output (neuron) is in the bit lines BL0-BLN, where each bit line sums all currents from the non-volatile memory cells connected to that particular bitline.

Table No. 8 depicts operating voltages and currents for VMM array 1300. The columns in the table indicate the voltages placed on word lines for selected cells, word lines for unselected cells, bit lines for selected cells, bit lines for unselected cells, control gates for selected cells, control gates for unselected cells in the same sector as the selected cells, control gates for unselected cells in a different sector than the selected cells, erase gates for selected cells, erase gates for unselected cells, source lines for selected cells, and source lines for unselected cells. The rows indicate the operations of read, erase, and program.

TABLE NO 8
Operation of VMM Array 1300 of FIG. 13

| | | | | | | | | | | CG -unsel | | | | | | | | | | | |
|---|---|---|---|---|---|---|---|---|---|---|---|---|---|---|---|---|---|---|---|---|---|
| | | | WL - | | | BL - | | | | same | | CG - | | | | EG - | | | | SL - | |
| | WL | | unsel | BL | | unsel | | CG | | sector | | unsel | | EG | | unsel | | SL | | unsel | |
| Read | 1.0-2 | V | −0.5 V/0 V | 0.6-2 | V | 0 | V | 0-2.6 | V | 0-2.6 | V | 0-2.6 | V | 0-2.6 | V | 0-2.6 | V | 0 | V | 0 | V |
| | | | | (Ineuron) | | | | | | | | | | | | | | | | | |
| Erase | 0 | V | 0 V | 0 | V | 0 | V | 0 | V | 4-9 | V | 0-2.6 | V | 5-12 | V | 0-2.6 | V | 0 | V | 0 | V |

| | | | | | | | | | | | | | | | | | | | | |
|---|---|---|---|---|---|---|---|---|---|---|---|---|---|---|---|---|---|---|---|---|
| Program | 0.7-1 | V | −0.5 V/0 V | 0.1-1 | uA | Vinh | 4-11 | V | 0-2.6 | V | 0-2.6 | V | 4.5-5 | V | 0-2.6 | V | 4.5-5 | V | 0-1 | V |

(1-2 V)

FIG. 22 depicts neuron VMM array 2200, which is particularly suited for memory cells 210 as shown in FIG. 2 and is utilized as the synapses and parts of neurons between an input layer and the next layer. In VMM array 2200, the inputs INPUT₀ . . . , INPUT_{N} are received on bit lines BL₀, . . . . BL_{N}, respectively, and the outputs OUTPUT₁, OUTPUT₂, OUTPUT₃, and OUTPUT₄ are generated on source lines SL₀, SL₁, SL₂, and SL₃, respectively.

FIG. 23 depicts neuron VMM array 2300, which is particularly suited for memory cells 210 as shown in FIG. 2 and is utilized as the synapses and parts of neurons between an input layer and the next layer. In this example, the inputs INPUT₀, INPUT₁, INPUT₂, and INPUT₃ are received on source lines SL₀, SL₁, SL₂, and SL₃, respectively, and the outputs OUTPUT₀, . . . . OUTPUT_{N} are generated on bit lines BL₀, . . . , BL_{N}.

FIG. 24 depicts neuron VMM array 2400, which is particularly suited for memory cells 210 as shown in FIG. 2 and is utilized as the synapses and parts of neurons between an input layer and the next layer. In this example, the inputs INPUT₀, . . . , INPUT_{M} are received on word lines WL₀, . . . , WL_{M}, respectively, and the outputs OUTPUT₀, . . . . OUTPUT_{N} are generated on bit lines BL₀, . . . , BL_{N}.

FIG. 25 depicts neuron VMM array 2500, which is particularly suited for memory cells 310 as shown in FIG. 3 and is utilized as the synapses and parts of neurons between an input layer and the next layer. In this example, the inputs INPUT₀ . . . , INPUT_{M} are received on word lines WL₀, . . . , WL_{M}, respectively, and the outputs OUTPUT₀, . . . . OUTPUT_{N} are generated on bit lines BL₀, . . . , BL_{N}.

FIG. 26 depicts neuron VMM array 2600, which is particularly suited for memory cells 410 as shown in FIG. 4 and is utilized as the synapses and parts of neurons between an input layer and the next layer. In this example, the inputs INPUT₀, . . . , INPUTₙ are received on vertical control gate lines CG₀, . . . , CG_{N}, respectively, and the outputs OUTPUT₁ and OUTPUT₂ are generated on source lines SL₀ and SL₁.

FIG. 27 depicts neuron VMM array 2700, which is particularly suited for memory cells 410 as shown in FIG. 4 and is utilized as the synapses and parts of neurons between an input layer and the next layer. In this example, the inputs INPUT₀ . . . , INPUT_{N} are received on the gates of bit line control gates 2701-1, 2701-2, . . . , 2701-(N−1), and 2701-N, respectively, which are coupled to bit lines BL₀, . . . , BL_{N}, respectively. Example outputs OUTPUT₁ and OUTPUT₂ are generated on source lines SL₀ and SL₁.

FIG. 28 depicts neuron VMM array 2800, which is particularly suited for memory cells 310 as shown in FIG. 3, memory cells 510 as shown in FIG. 5, and memory cells 710 as shown in FIG. 7, and is utilized as the synapses and parts of neurons between an input layer and the next layer. In this example, the inputs INPUT₀ . . . , INPUT_{M} are received on word lines WL₀, . . . , WL_{M}, and the outputs OUTPUT₀ . . . , OUTPUT_{N} are generated on bit lines BL₀, . . . , BL_{N}, respectively.

FIG. 29 depicts neuron VMM array 2900, which is particularly suited for memory cells 310 as shown in FIG. 3, memory cells 510 as shown in FIG. 5, and memory cells 710 as shown in FIG. 7, and is utilized as the synapses and parts of neurons between an input layer and the next layer. In this example, the inputs INPUT₀ . . . , INPUT_{M} are received on control gate lines CG₀, . . . , CG_{M}. Outputs OUTPUT₀ . . . , OUTPUT_{N} are generated on vertical source lines SL₀, . . . , SL_{N}, respectively, where each source line SLᵢ is coupled to the source lines of all memory cells in column i.

FIG. 30 depicts neuron VMM array 3000, which is particularly suited for memory cells 310 as shown in FIG. 3, memory cells 510 as shown in FIG. 5, and memory cells 710 as shown in FIG. 7, and is utilized as the synapses and parts of neurons between an input layer and the next layer. In this example, the inputs INPUT₀ . . . , INPUT_{M} are received on control gate lines CG₀, . . . , CG_{M}. Outputs OUTPUT₀, . . . , OUTPUT_{N} are generated on vertical bit lines BL₀, . . . . BL_{N}, respectively, where each bit line BLᵢ is coupled to the bit lines of all memory cells in column i.

### Long Short-Term Memory

The prior art includes a concept referred to as long short-term memory (LSTM). LSTM units often are used in neural networks. LSTM allows a neural network to remember information over predetermined arbitrary time intervals and to use that information in subsequent operations. A conventional LSTM unit comprises a cell, an input gate, an output gate, and a forget gate. The three gates regulate the flow of information into and out of the cell and the time interval that the information is remembered in the LSTM. VMMs are particularly useful in LSTM units.

FIG. 14 depicts an example LSTM 1400. LSTM 1400 in this example comprises cells 1401, 1402, 1403, and 1404. Cell 1401 receives input vector x₀ and generates output vector h₀ and cell state vector c₀. Cell 1402 receives input vector x₁, the output vector (hidden state) h₀ from cell 1401, and cell state c₀ from cell 1401 and generates output vector h₁ and cell state vector c₁. Cell 1403 receives input vector x₂, the output vector (hidden state) h₁ from cell 1402, and cell state c₁ from cell 1402 and generates output vector h₂ and cell state vector c₂. Cell 1404 receives input vector x₃, the output vector (hidden state) h₂ from cell 1403, and cell state c₂ from cell 1403 and generates output vector h₃. Additional cells can be used, and an LSTM with four cells is merely an example.

FIG. 15 depicts an example implementation of an LSTM cell 1500, which can be used for cells 1401, 1402, 1403, and 1404 in FIG. 14. LSTM cell 1500 receives input vector x(t), cell state vector c(t−1) from a preceding cell, and output vector h(t−1) from a preceding cell, and generates cell state vector c(t) and output vector h(t).

LSTM cell 1500 comprises sigmoid function devices 1501, 1502, and 1503, each of which applies a number between 0 and 1 to control how much of each component in the input vector is allowed through to the output vector. LSTM cell 1500 also comprises tanh devices 1504 and 1505 to apply a hyperbolic tangent function to an input vector, multiplier devices 1506, 1507, and 1508 to multiply two vectors together, and addition device 1509 to add two vectors together. Output vector h(t) can be provided to the next LSTM cell in the system, or it can be accessed for other purposes.

FIG. 16 depicts an LSTM cell 1600, which is an example of an implementation of LSTM cell 1500. For the reader's convenience, the same numbering from LSTM cell 1500 is used in LSTM cell 1600. Sigmoid function devices 1501, 1502, and 1503 and tanh device 1504 each comprise multiple VMM arrays 1601 and activation function blocks 1602. Thus, it can be seen that VMM arrays are particular useful in LSTM cells used in certain neural network systems. The multiplier devices 1506, 1507, and 1508 and the addition device 1509 are implemented in a digital manner or in an analog manner. The activation function blocks 1602 can be implemented in a digital manner or in an analog manner.

An alternative to LSTM cell 1600 (and another example of an implementation of LSTM cell 1500) is shown in FIG. 17. In FIG. 17, sigmoid function devices 1501, 1502, and 1503 and tanh device 1504 share the same physical hardware (VMM arrays 1701 and activation function block 1702) in a time-multiplexed fashion. LSTM cell 1700 also comprises multiplier device 1703 to multiply two vectors together, addition device 1708 to add two vectors together, tanh device 1505 (which comprises activation function block 1702), register 1707 to store the value i(t) when i(t) is output from sigmoid function block 1702, register 1704 to store the value f(t)*c(t−1) when that value is output from multiplier device 1703 through multiplexor 1710, register 1705 to store the value i(t)*u(t) when that value is output from multiplier device 1703 through multiplexor 1710, and register 1706 to store the value o(t)*c˜(t) when that value is output from multiplier device 1703 through multiplexor 1710, and multiplexor 1709.

Whereas LSTM cell 1600 contains multiple sets of VMM arrays 1601 and respective activation function blocks 1602, LSTM cell 1700 contains one set of VMM arrays 1701 and activation function block 1702, which are used to represent multiple layers in the example of LSTM cell 1700. LSTM cell 1700 will use less space than LSTM 1600, as LSTM cell 1700 will use ¼ as much space for VMMs and activation function blocks compared to LSTM cell 1600.

It can be further appreciated that LSTM units will typically comprise multiple VMM arrays, each of which uses functionality provided by certain circuit blocks outside of the VMM arrays, such as a summer and activation function block and high voltage generation blocks. Providing separate circuit blocks for each VMM array would use a significant amount of space within the semiconductor device and would be somewhat inefficient. The examples described below therefore reduce the circuitry used outside of the VMM arrays themselves.

### Gated Recurrent Units

An analog VMM implementation can be utilized for a GRU (gated recurrent unit) system. GRUs are a gating mechanism in recurrent neural networks. GRUs are similar to LSTMs, except that GRU cells generally contain fewer components than an LSTM cell.

FIG. 18 depicts an example GRU 1800. GRU 1800 in this example comprises cells 1801, 1802, 1803, and 1804. Cell 1801 receives input vector x₀ and generates output vector h₀. Cell 1802 receives input vector x₁, the output vector h₀ from cell 1801 and generates output vector h₁. Cell 1803 receives input vector x₂ and the output vector (hidden state) h₁ from cell 1802 and generates output vector h₂. Cell 1804 receives input vector x₃ and the output vector (hidden state) h₂ from cell 1803 and generates output vector h₃. Additional cells can be used, and an GRU with four cells is merely an example.

FIG. 19 depicts an example implementation of a GRU cell 1900, which can be used for cells 1801, 1802, 1803, and 1804 of FIG. 18. GRU cell 1900 receives input vector x(t) and output vector h(t−1) from a preceding GRU cell and generates output vector h(t). GRU cell 1900 comprises sigmoid function devices 1901 and 1902, each of which applies a number between 0 and 1 to components from output vector h(t−1) and input vector x(t). GRU cell 1900 also comprises a tanh device 1903 to apply a hyperbolic tangent function to an input vector, a plurality of multiplier devices 1904, 1905, and 1906 to multiply two vectors together, an addition device 1907 to add two vectors together, and a complementary device 1908 to subtract an input from 1 to generate an output.

FIG. 20 depicts a GRU cell 2000, which is an example of an implementation of GRU cell 1900. For the reader's convenience, the same numbering from GRU cell 1900 is used in GRU cell 2000. As can be seen in FIG. 20, sigmoid function devices 1901 and 1902, and tanh device 1903 each comprise multiple VMM arrays 2001 and activation function blocks 2002. Thus, it can be seen that VMM arrays are of particular use in GRU cells used in certain neural network systems. The multiplier devices 1904, 1905, 1906, the addition device 1907, and the complementary device 1908 are implemented in a digital manner or in an analog manner. The activation function blocks 2002 can be implemented in a digital manner or in an analog manner.

An alternative to GRU cell 2000 (and another example of an implementation of GRU cell 1900) is shown in FIG. 21. In FIG. 21, GRU cell 2100 utilizes VMM arrays 2101 and activation function block 2102, which when configured as a sigmoid function applies a number between 0 and 1 to control how much of each component in the input vector is allowed through to the output vector. In FIG. 21, sigmoid function devices 1901 and 1902 and tanh device 1903 share the same physical hardware (VMM arrays 2101 and activation function block 2102) in a time-multiplexed fashion. GRU cell 2100 also comprises multiplier device 2103 to multiply two vectors together, addition device 2105 to add two vectors together, complementary device 2109 to subtract an input from 1 to generate an output, multiplexor 2104, register 2106 to hold the value h(t−1)*r(t) when that value is output from multiplier device 2103 through multiplexor 2104, register 2107 to hold the value h(t−1)*z(t) when that value is output from multiplier device 2103 through multiplexor 2104, and register 2108 to hold the value h\hat{ }(t)*(1−z(t)) when that value is output from multiplier device 2103 through multiplexor 2104.

Whereas GRU cell 2000 contains multiple sets of VMM arrays 2001 and activation function blocks 2002, GRU cell 2100 contains one set of VMM arrays 2101 and activation function block 2102, which are used to represent multiple layers in the example of GRU cell 2100. GRU cell 2100 will use less space than GRU cell 2000, as GRU cell 2100 will use ⅓ as much space for VMMs and activation function blocks compared to GRU cell 2000.

It can be further appreciated that GRU systems will typically comprise multiple VMM arrays, each of which uses functionality provided by certain circuit blocks outside of the VMM arrays, such as a summer and activation function block and high voltage generation blocks. Providing separate circuit blocks for each VMM array would use a significant amount of space within the semiconductor device and would be somewhat inefficient. The examples described below therefore reduce the circuitry used outside of the VMM arrays themselves.

The input to the VMM arrays can be an analog level, a binary level, a pulse, a time modulated pulse, or digital bits (in this case a DAC is used to convert digital bits to appropriate input analog level) and the output can be an analog level, a binary level, a timing pulse, pulses, or digital bits (in this case an output ADC is used to convert output analog level into digital bits).

In general, for each memory cell in a VMM array, each weight W can be implemented by a single memory cell or by a differential cell or by two blend memory cells (average of 2 cells). In the differential cell case, two memory cells are used to implement a weight W as a differential weight (W=W+−W−). In the two blend memory cells, two memory cells are used to implement a weight W as an average of two cells.

FIG. 31 depicts VMM system 3100. In some examples, the weights, W, stored in a VMM array are stored as differential pairs, W+ (positive weight) and W− (negative weight), where W=(W+)−(W−). In VMM system 3100, half of the bit lines are designated as W+ lines, that is, bit lines connecting to memory cells that will store positive weights W+, and the other half of the bit lines are designated as W− lines, that is, bit lines connecting to memory cells implementing negative weights W−. The W− lines are interspersed among the W+ lines in an alternating fashion. The subtraction operation is performed by a summation circuit that receives current from a W+ line and a W− line, such as summation circuits 3101 and 3102. The output of a W+ line and the output of a W− line are combined together to give effectively W=W+−W− for each pair of (W+, W−) cells for all pairs of (W+, W−) lines. While the above has been described in relation to W− lines interspersed among the W+ lines in an alternating fashion, in other examples W+ lines and W− lines can be arbitrarily located anywhere in the array.

FIG. 32 depicts another example. In VMM system 3210, positive weights W+ are implemented in first array 3211 and negative weights W− are implemented in a second array 3212, second array 3212 separate from the first array, and the resulting weights are appropriately combined together by summation circuits 3213.

FIG. 33 depicts VMM system 3300. the weights, W, stored in a VMM array are stored as differential pairs, W+ (positive weight) and W− (negative weight), where W=(W+)−(W−). VMM system 3300 comprises array 3301 and array 3302. Half of the bit lines in each of array 3301 and 3302 are designated as W+ lines, that is, bit lines connecting to memory cells that will store positive weights W+, and the other half of the bit lines in each of array 3301 and 3302 are designated as W− lines, that is, bit lines connecting to memory cells implementing negative weights W−. The W− lines are interspersed among the W+ lines in an alternating fashion. The subtraction operation is performed by a summation circuit that receives current from a W+ line and a W− line, such as summation circuits 3303, 3304, 3305, and 3306. The output of a W+ line and the output of a W− line from each array 3301, 3302 are respectively combined together to give effectively W=W+−W− for each pair of (W+, W−) cells for all pairs of (W+, W−) lines. In addition, the W values from each array 3301 and 3302 can be further combined through summation circuits 3307 and 3308, such that each W value is the result of a W value from array 3301 minus a W value from array 3302, meaning that the end result from summation circuits 3307 and 3308 is a differential value of two differential values.

As discussed above, neural networks can comprise a plurality of layers. Each layer can represent different data patterns or different features resulting in different output ranges for the array outputs for the vector-by-matric multiplication array. An analog-to-digital converter (ADC) often is used to convert the array output into digital bits. A current-to-voltage converter (ITV) may be used to convert the analog output current from the array into an analog voltage, and the analog voltage then can be converted into digital bits by the ADC.

Because the output ranges can vary from layer to layer in the neural network, it would be desirable to be able to configure the ADC and ITV to alter the range of the outputs provided by each layer. Optionally, this configuration can cause the outputs of all layers to fall within a certain range of possible outputs.

### SUMMARY OF THE INVENTION

Numerous examples are disclosed of configurable input and output blocks and associated methods for a neural network array.

In one example, a system comprises a vector-by-matrix multiplication array comprising non-volatile memory cells arranged into rows and columns; and an output block coupled to the vector-by-matrix multiplication array to receive current from the columns of the array, the output block comprising: a current-to-voltage converter to receive current from one or two columns and convert the current into a voltage, the current-to-voltage converter comprising one or more variable resistors configurable to adjust a range of possible voltages of the voltage; and an analog-to-digital converter to convert the voltage into digital bits.

In another example, a system comprises a vector-by-matrix multiplication array comprising non-volatile memory cells arranged into rows and columns; and an output block coupled to the vector-by-matrix multiplication array to receive current from the columns of the array, the output block comprising: a current-to-voltage converter to receive current from one or two columns and convert the current into a voltage, the current-to-voltage converter comprising one or more variable capacitors configurable to adjust a range of possible voltages of the voltage; and an analog-to-digital converter to convert the voltage into digital bits.

In another example, a system comprises a vector-by-matrix multiplication array comprising non-volatile memory cells arranged into rows and columns; and an input block comprising: a global digital-to-analog converter to generate 2^{m} different analog voltages, where m is an integer; and a plurality of row circuits, each row circuit comprising: an address decoder to receive a row address and output an enable signal in response to the row address; a row register storing activation data and outputting the activation data when the enable signal from the address decoder is asserted; a selector to select and output one of the 2^{m} different analog voltages in response to the activation data; a buffer to output the voltage received from the selector; and a multiplexor to select a voltage received from the buffer or a voltage received from the selector and apply the selected voltage to a row in the vector-by-matrix multiplication array.

In another example, a system comprises a vector-by-matrix multiplication array comprising non-volatile memory cells arranged into rows and columns; and an input block configured based on a number of enabled rows.

In another example, a method comprises configuring an input block based on a number of rows that are enabled in a vector-by-matrix multiplication array comprising non-volatile memory cells arranged into rows and columns; and converting inputs into voltages applied to the enable rows.

In another example, a method comprises receiving differential bitline currents comprising a first current and a second current from a memory array; adding a first fixed bias current to the first current to generate a third current; adding a second fixed bias current to the second current to generate a fourth current; and converting the third current and the fourth current into digital output bits.

In another example, a method comprises receiving differential bitline currents comprising a first current and a second current from a memory array; adding a first fixed bias current to the first current to generate a third current; adding a second fixed bias current to the second current to generate a fourth current; during a first period, converting the first fixed bias and the second fixed bias into a first set of digital bits; and during a second period, converting the third current and the fourth current into a second set of digital bits.

### BRIEF DESCRIPTION OF THE DRAWINGS

FIG. 1 is a diagram that illustrates an artificial neural network.

FIG. 2 depicts a prior art split gate flash memory cell.

FIG. 3 depicts another prior art split gate flash memory cell.

FIG. 4 depicts another prior art split gate flash memory cell.

FIG. 5 depicts another prior art split gate flash memory cell.

FIG. 6 is a diagram illustrating the different levels of an example artificial neural network utilizing one or more non-volatile memory arrays.

FIG. 7 is a block diagram illustrating a VMM system.

FIG. 8 is a block diagram illustrates an example artificial neural network utilizing one or more VMM systems.

FIG. 9 depicts another example of a VMM system.

FIG. 10 depicts another example of a VMM system.

FIG. 11 depicts another example of a VMM system.

FIG. 12 depicts another example of a VMM system.

FIG. 13 depicts another example of a VMM system.

FIG. 14 depicts a prior art long short-term memory system.

FIG. 15 depicts an example cell for use in a long short-term memory system.

FIG. 16 depicts an example implementation of the cell of FIG. 15.

FIG. 17 depicts another example implementation of the cell of FIG. 15.

FIG. 18 depicts a prior art gated recurrent unit system.

FIG. 19 depicts an example cell for use in a gated recurrent unit system.

FIG. 20 depicts an example implementation t of the cell of FIG. 19.

FIG. 21 depicts another example implementation of the cell of FIG. 19.

FIG. 22 depicts another example of a VMM system.

FIG. 23 depicts another example of a VMM system.

FIG. 24 depicts another example of a VMM system.

FIG. 25 depicts another example of a VMM system.

FIG. 26 depicts another example of a VMM system.

FIG. 27 depicts another example of a VMM system.

FIG. 28 depicts another example of a VMM system.

FIG. 29 depicts another example of a VMM system.

FIG. 30 depicts another example of a VMM system.

FIG. 31 depicts another example of a VMM system.

FIG. 32 depicts another example of a VMM system.

FIG. 33 depicts another example of a VMM system.

FIG. 34 depicts another example of a VMM system.

FIG. 35A depicts an input block for a VMM system.

FIG. 35B depicts an input block for a VMM system.

FIG. 35C depicts an input block for a VMM system.

FIG. 36A depicts a voltage buffer.

FIG. 36B depicts another voltage buffer.

FIG. 37A depicts a global digital-to-analog converter.

FIG. 37B depicts another global digital-to-analog converter.

FIG. 37C depicts another global digital-to-analog converter.

FIG. 38A depicts voltages generated internally by the global digital-to-analog converters of FIGS. 37A to 37C according to a linear function.

FIG. 38B depicts voltages generated internally by the global digital-to-analog converters of FIGS. 37A to 37C according to a logarithmic function.

FIG. 39 depicts an output block for a VMM system.

FIG. 40A depicts an output block for a VMM system.

FIG. 40B depicts an output block for a VMM system.

FIG. 41A depicts an output block for a VMM system.

FIG. 41B depicts an output block for a VMM system.

FIG. 42 depicts an output block for a VMM system.

FIG. 43 depicts an output block for a VMM system.

FIG. 44 depicts an input serial approximation register analog-to-digital converter.

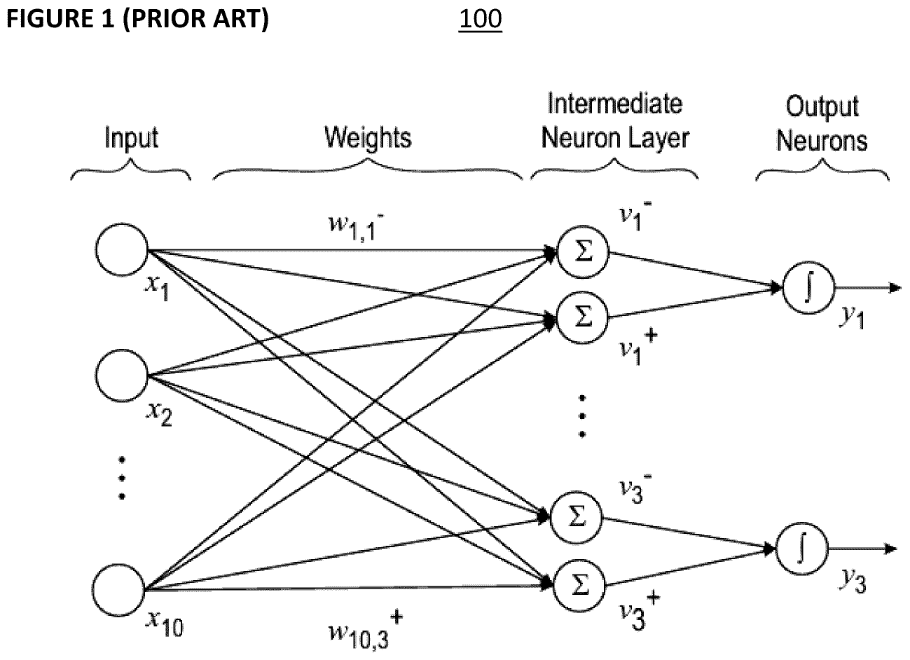

### DETAILED DESCRIPTION OF THE INVENTION

### VMM System Architecture

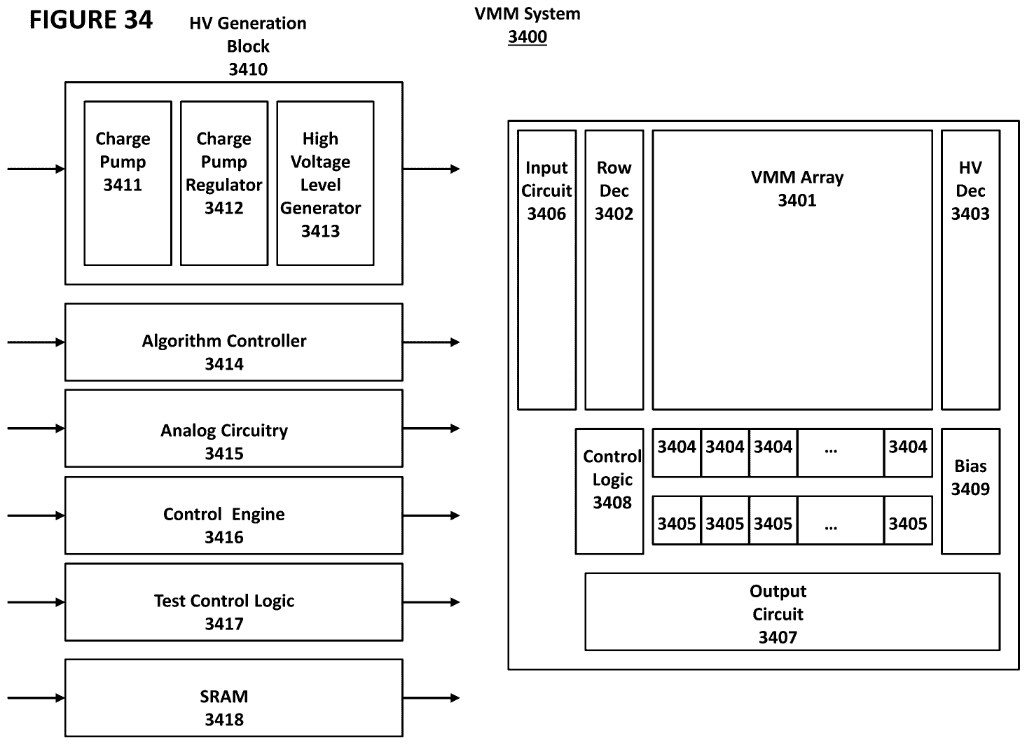

FIG. 34 depicts a block diagram of VMM system 3400. VMM system 3400 comprises VMM array 3401, row decoder 3402, high voltage decoder 3403, column decoders 3404, bit line drivers 3405 (such as bit line control circuitry for programming), input circuit 3406, output circuit 3407, control logic 3408, and bias generator 3409. VMM system 3400 further comprises high voltage generation block 3410, which comprises charge pump 3411, charge pump regulator 3412, and high voltage level generator 3413. VMM system 3400 further comprises (program/erase, or weight tuning) algorithm controller 3414, analog circuitry 3415, control engine 3416 (that may include functions such as arithmetic functions, activation functions, embedded microcontroller logic, without limitation), test control logic 3417, and static random access memory (SRAM) block 3418 to store intermediate data such as for input circuits (e.g., activation data) or output circuits (neuron output data, partial sum output neuron data) or data in for programming (such as data in for a whole row or for multiple rows).

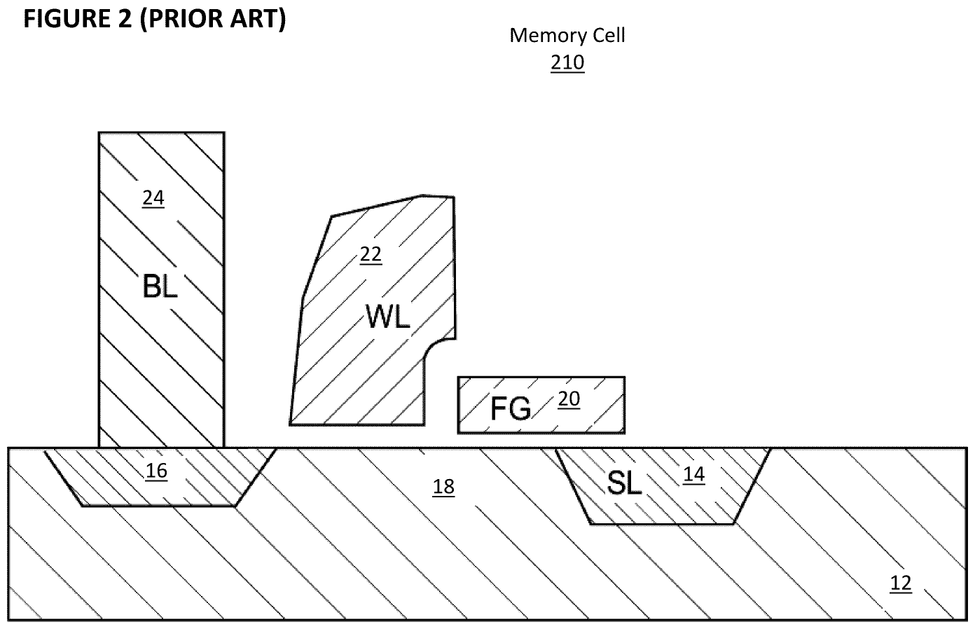

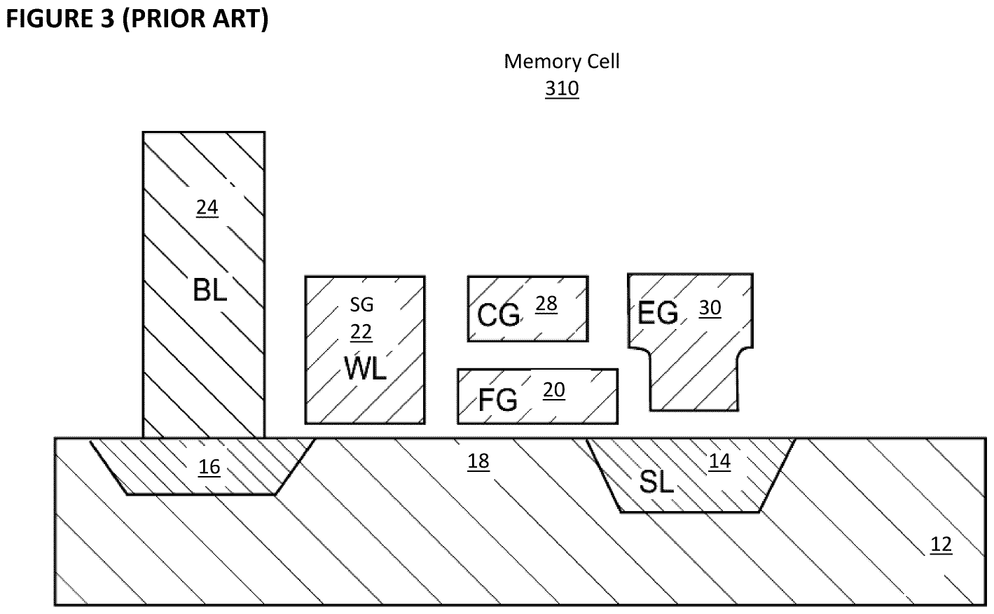

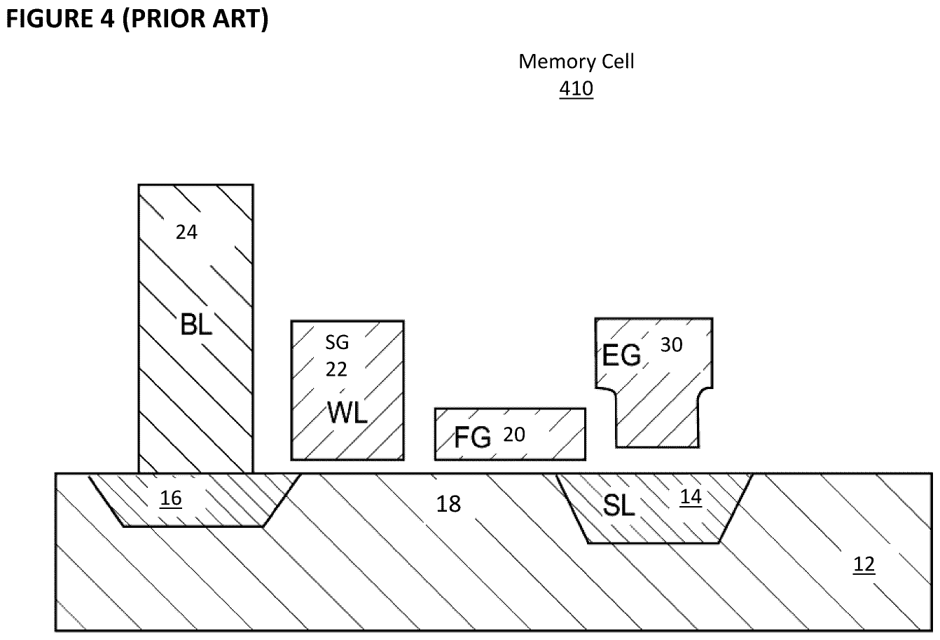

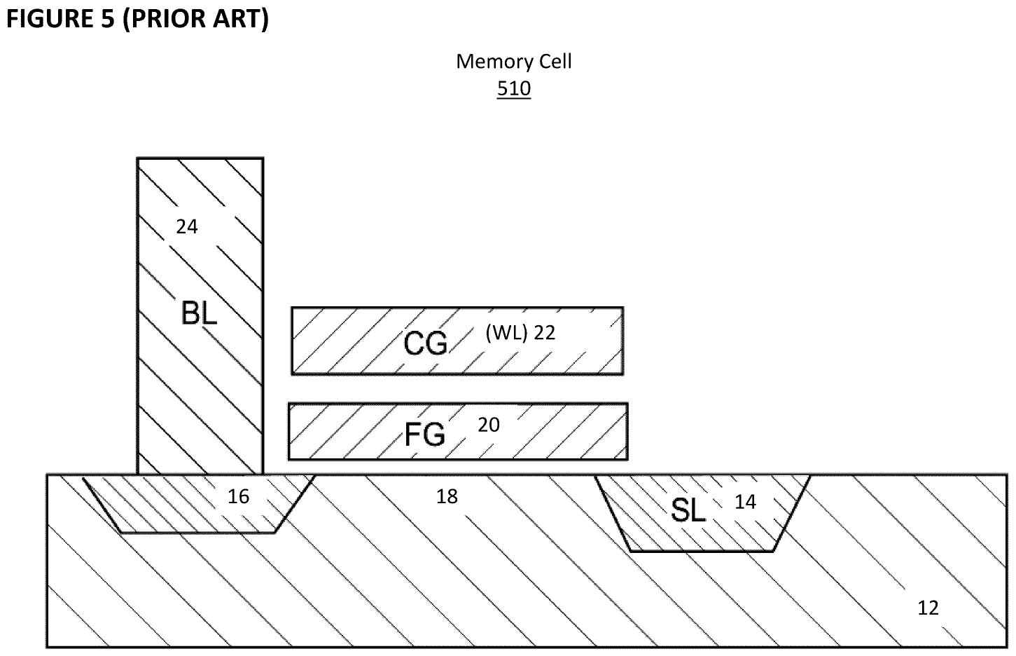

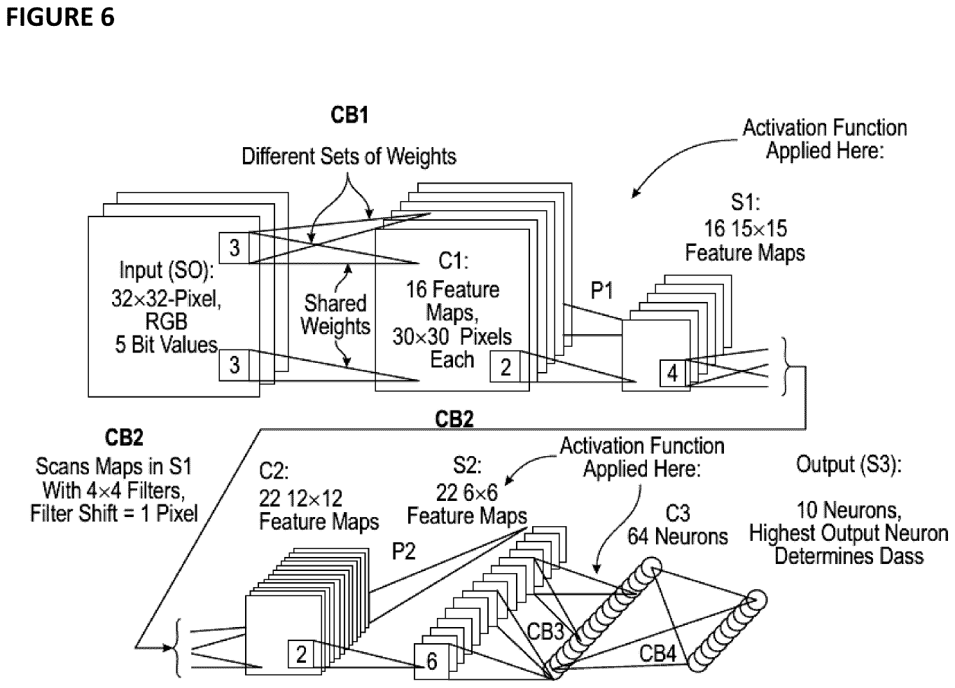

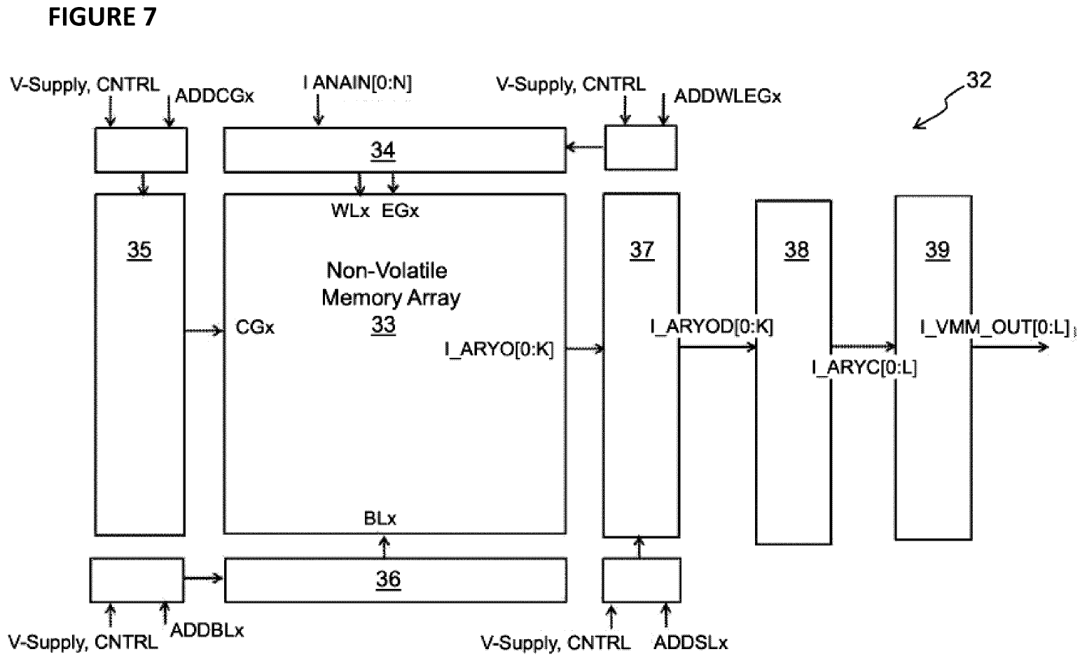

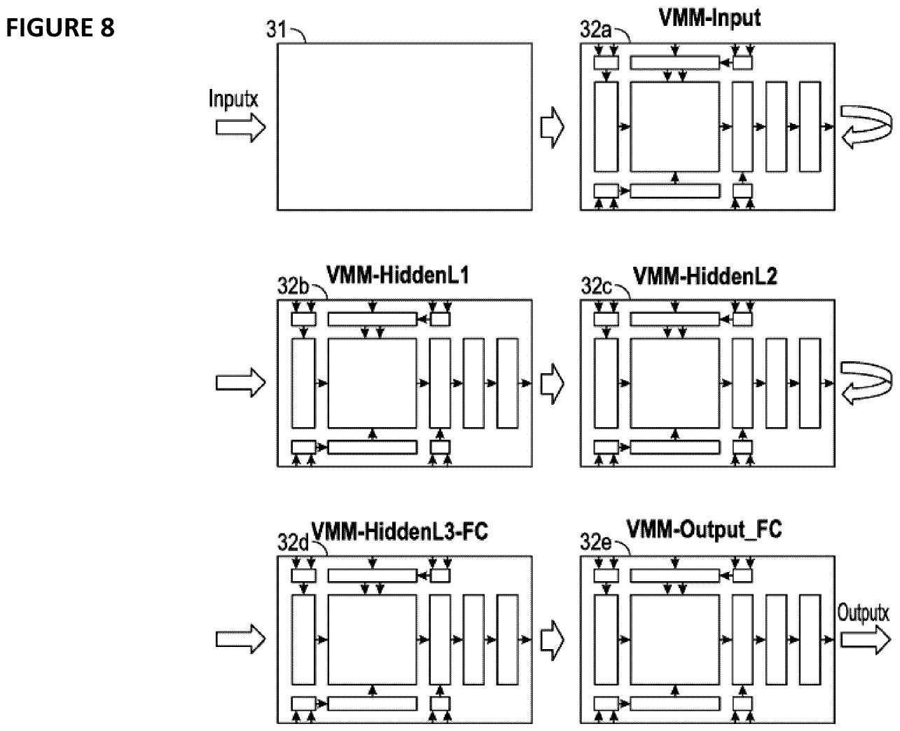

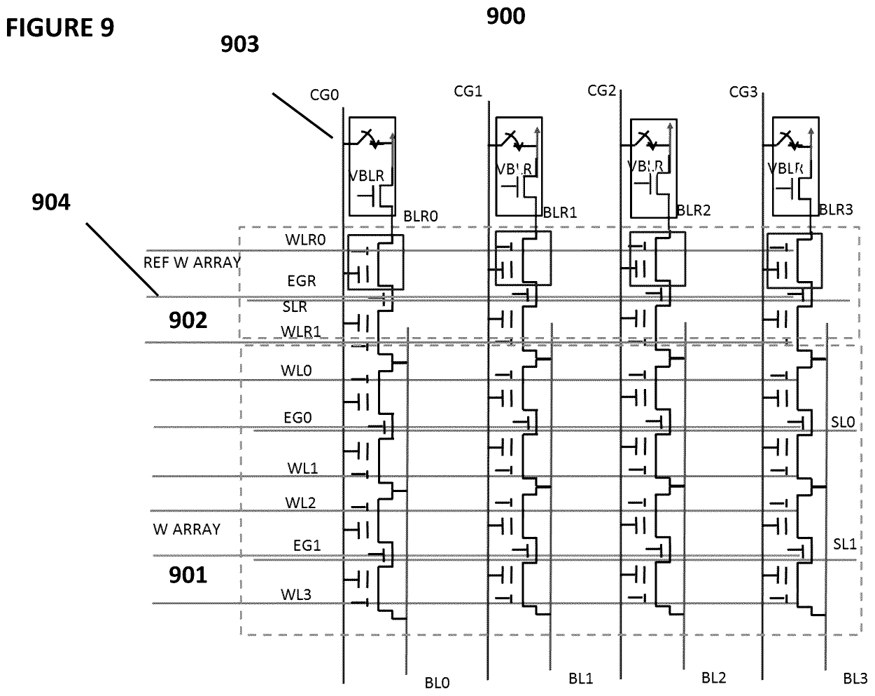

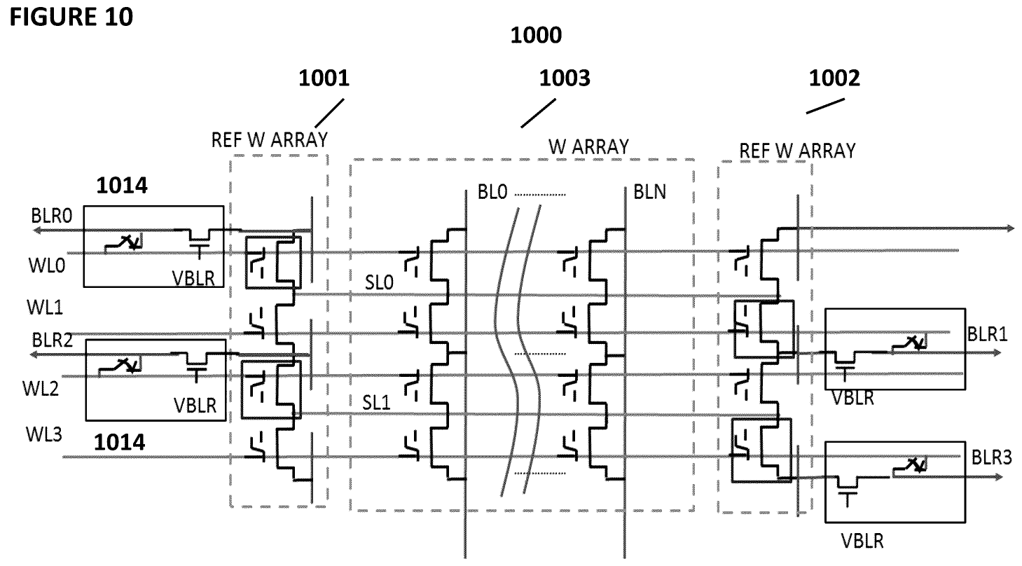

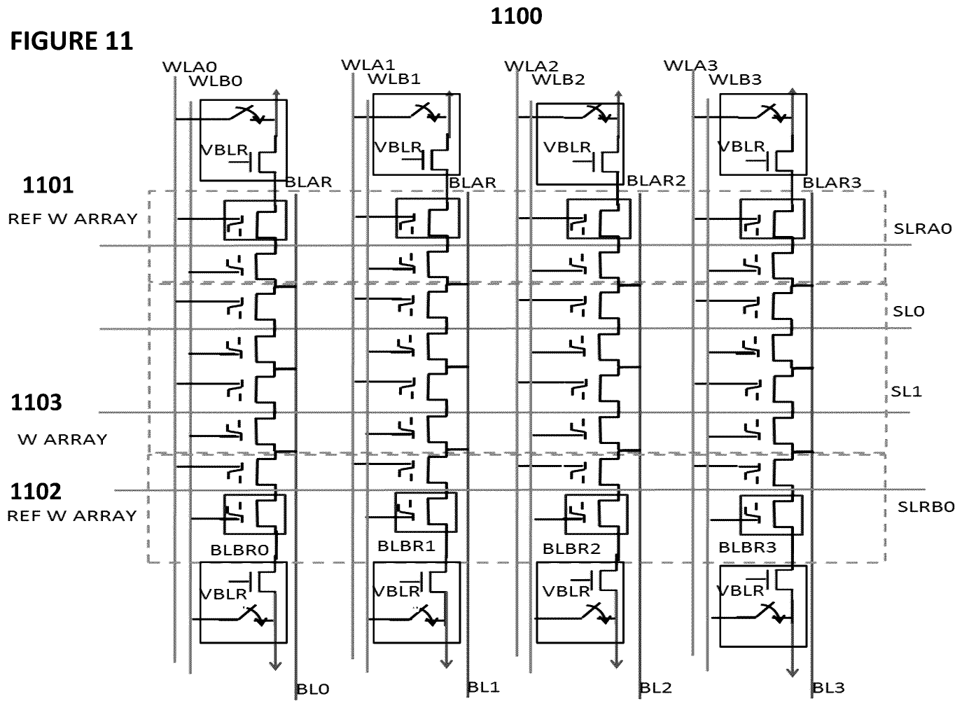

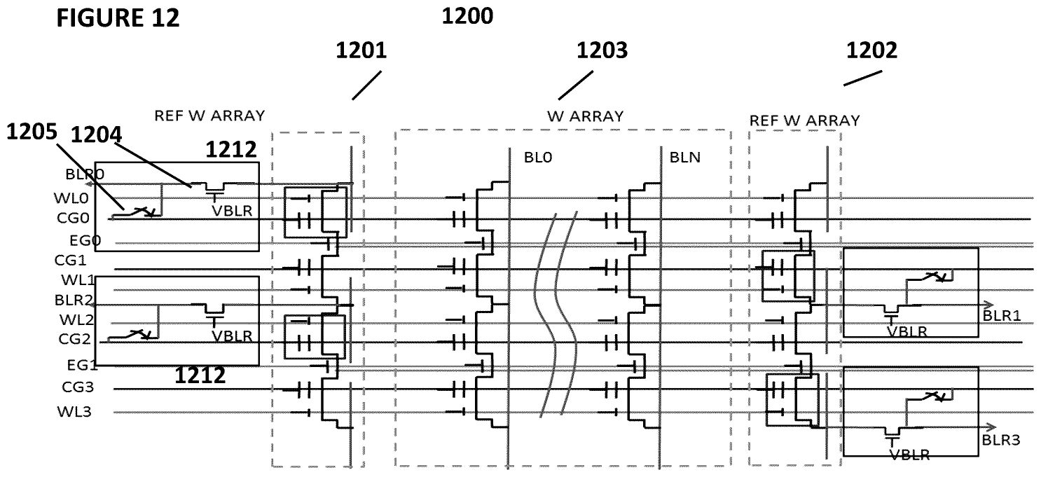

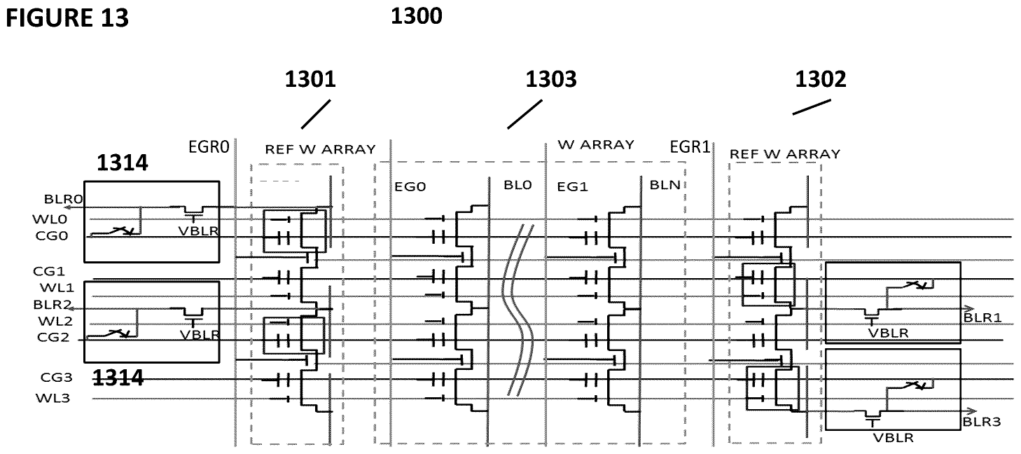

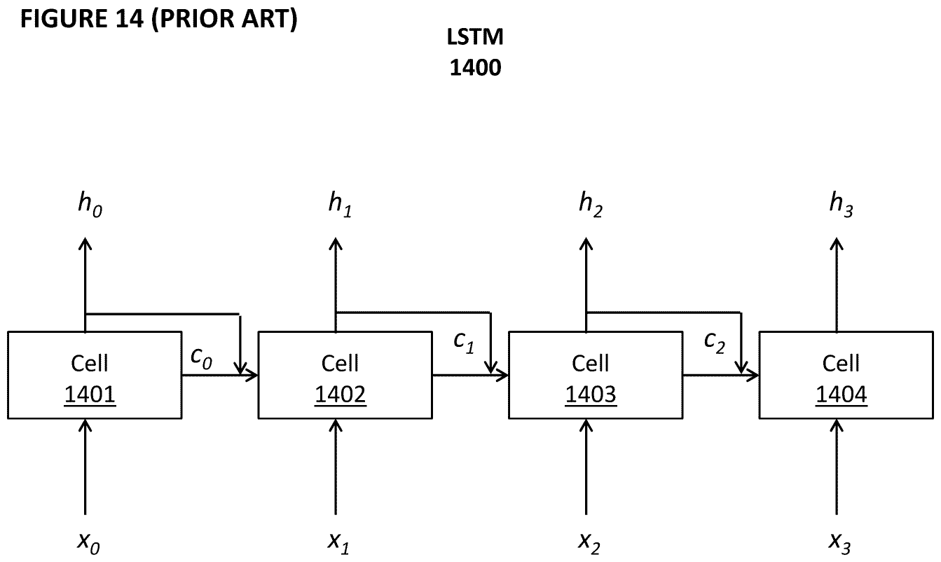

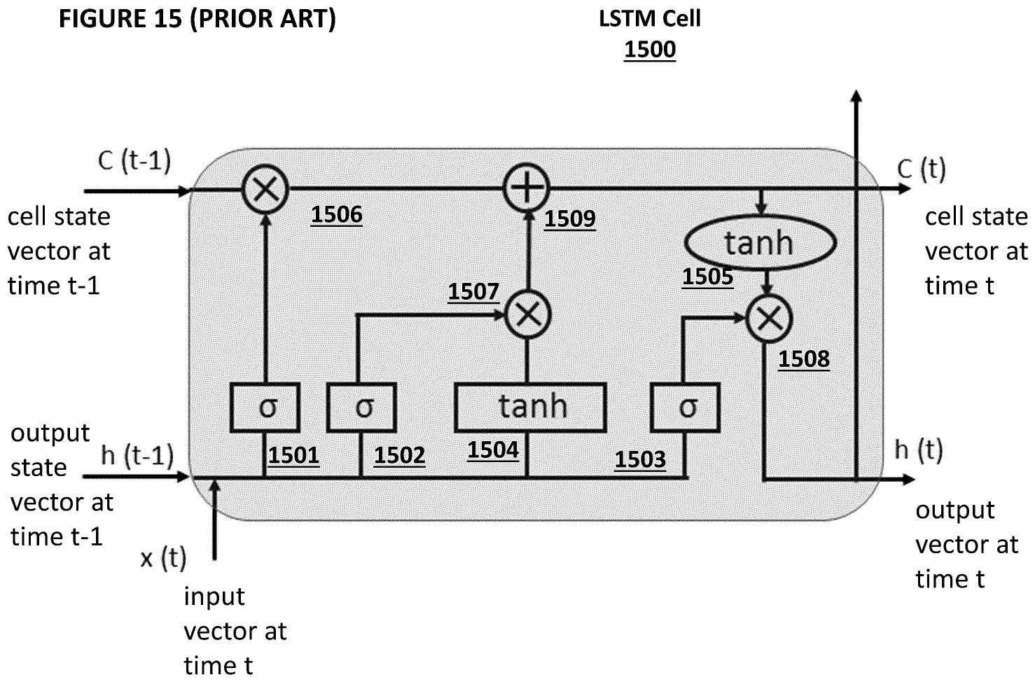

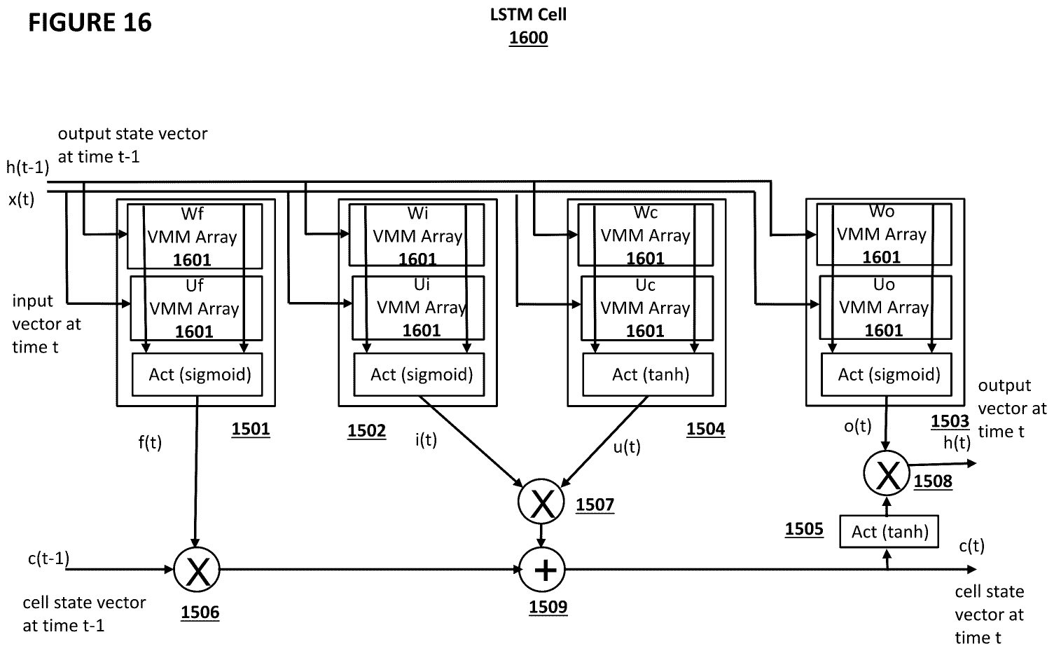

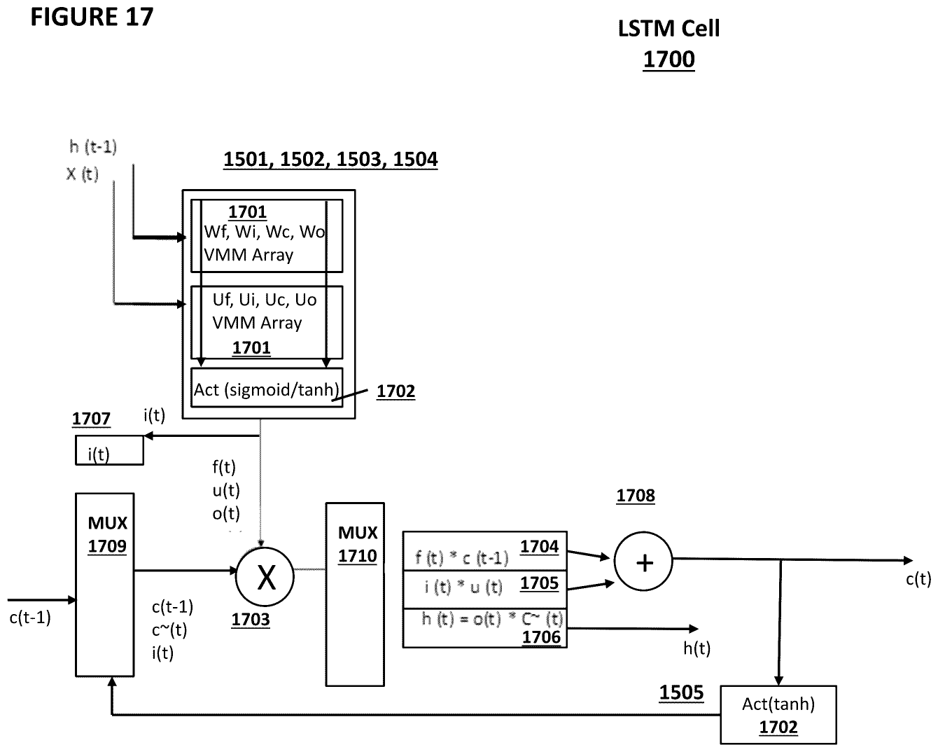

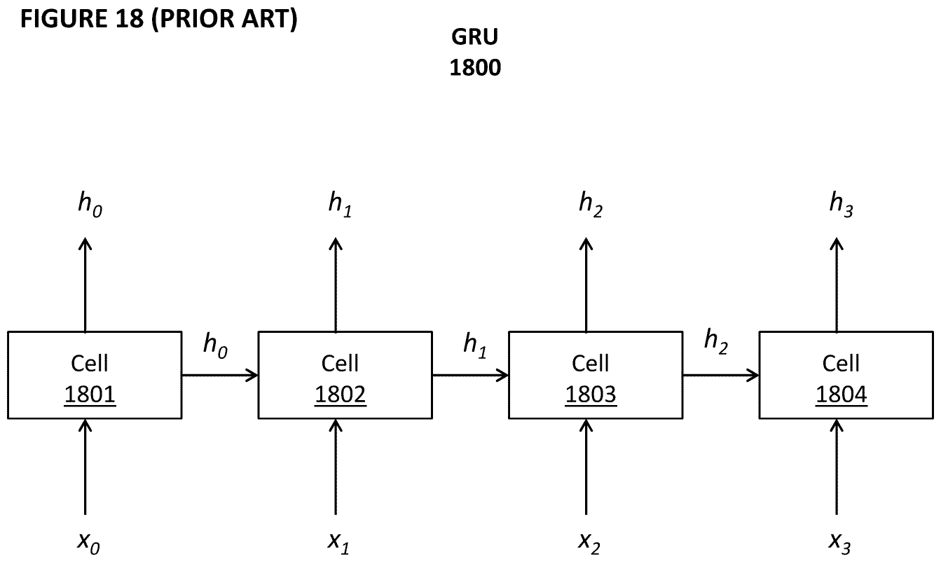

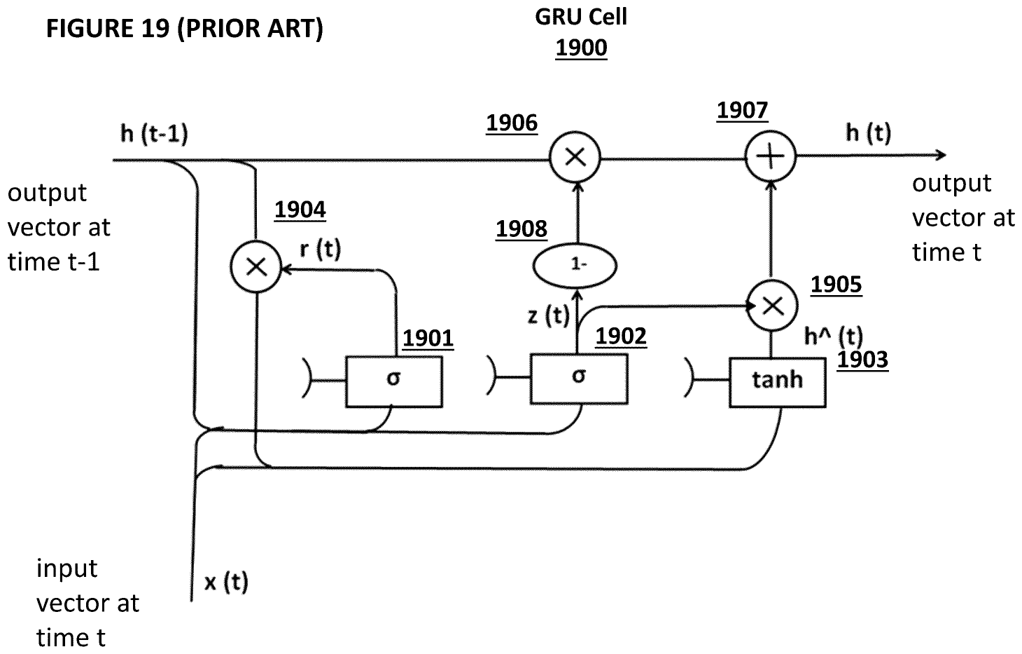

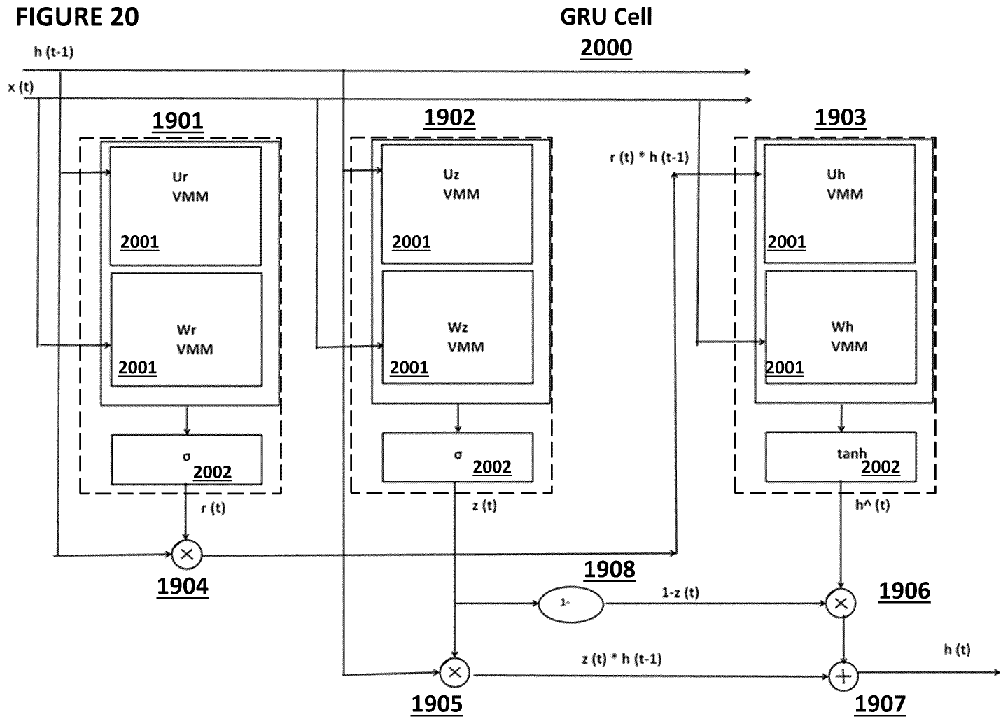

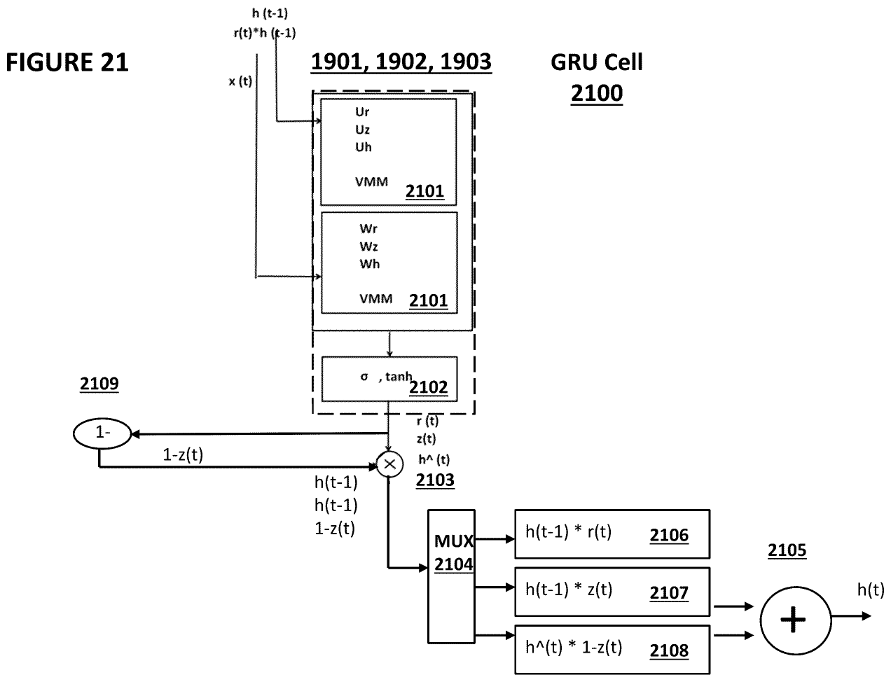

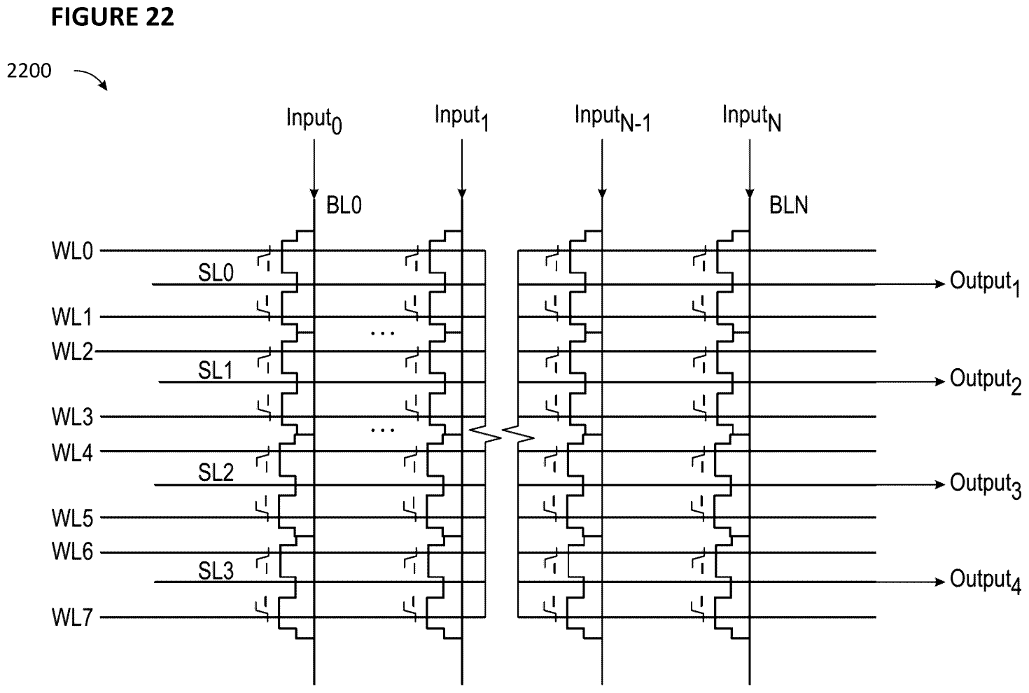

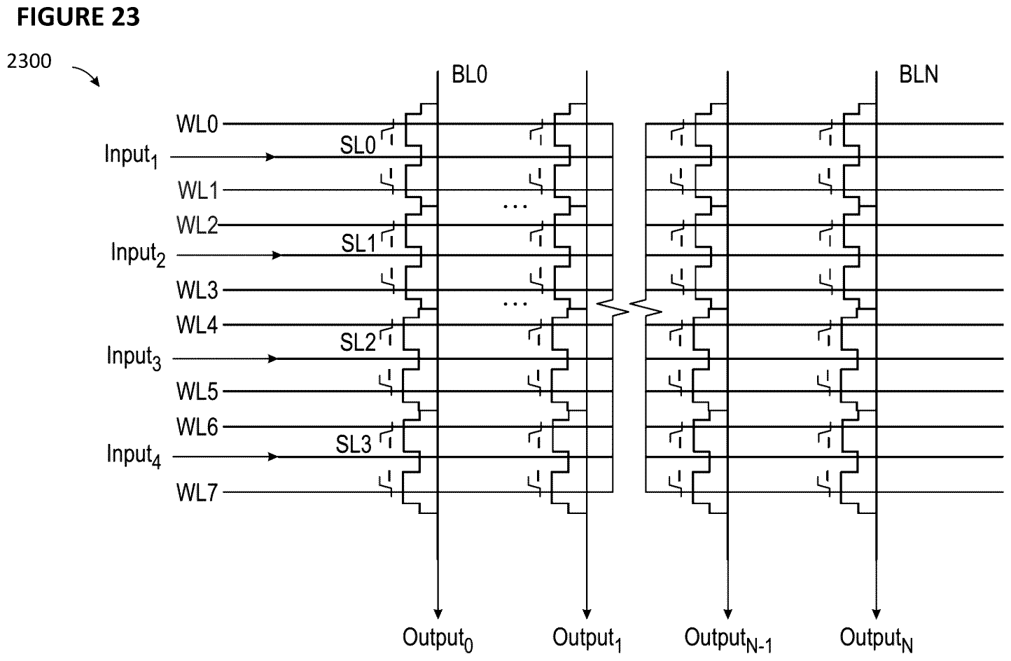

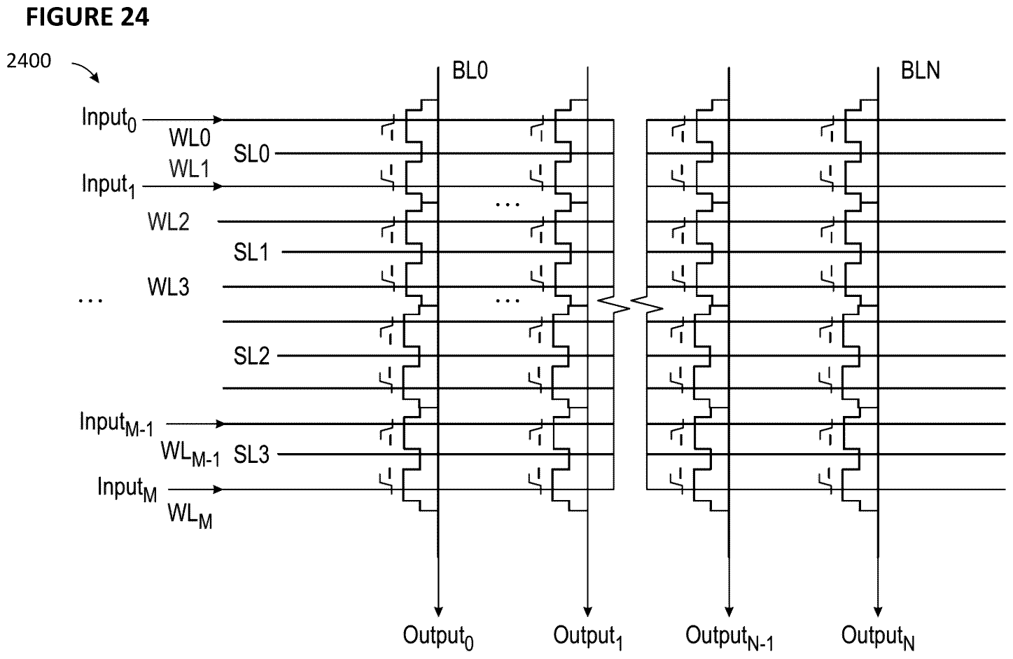

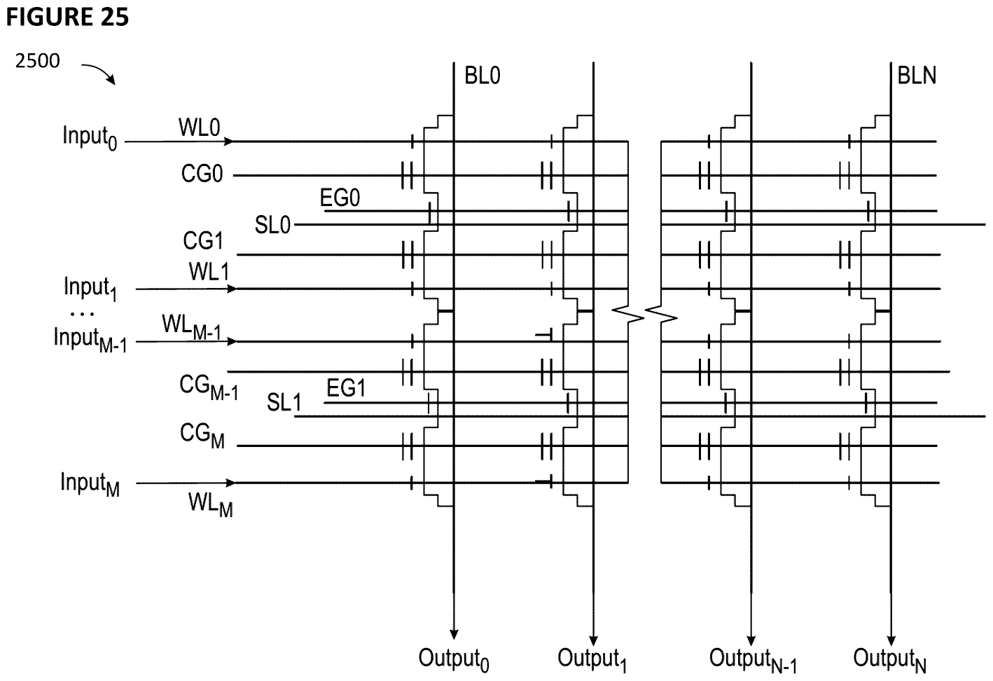

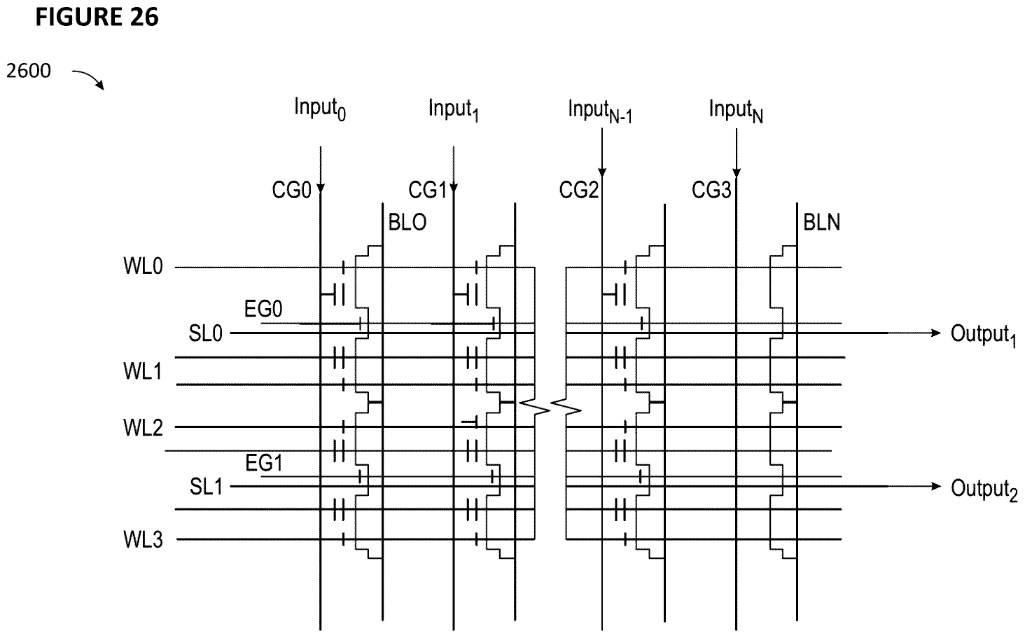

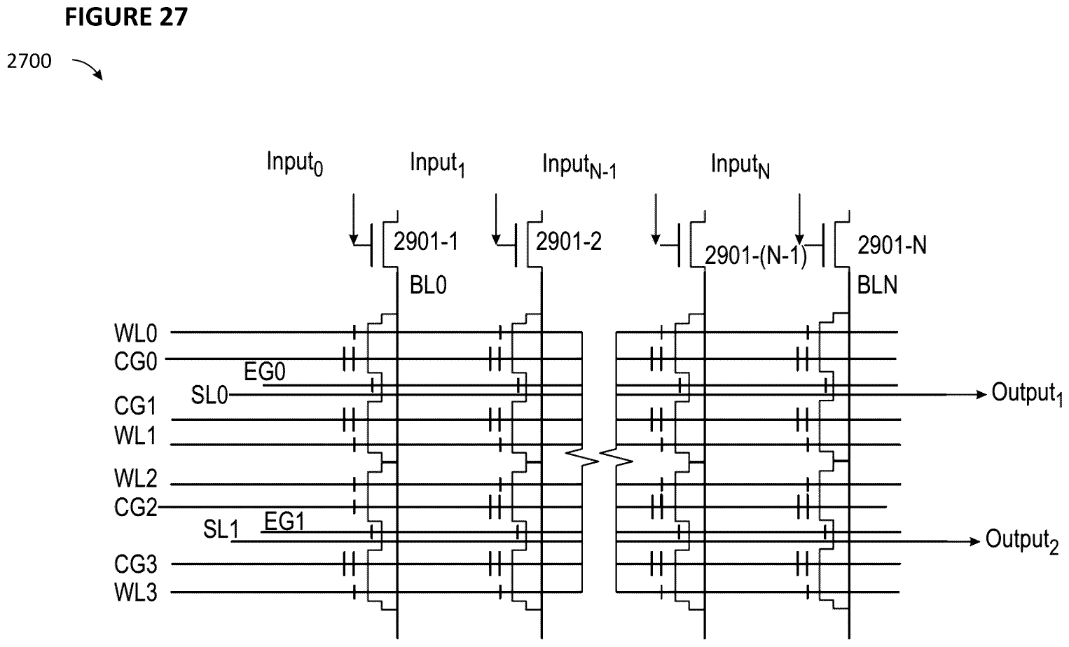

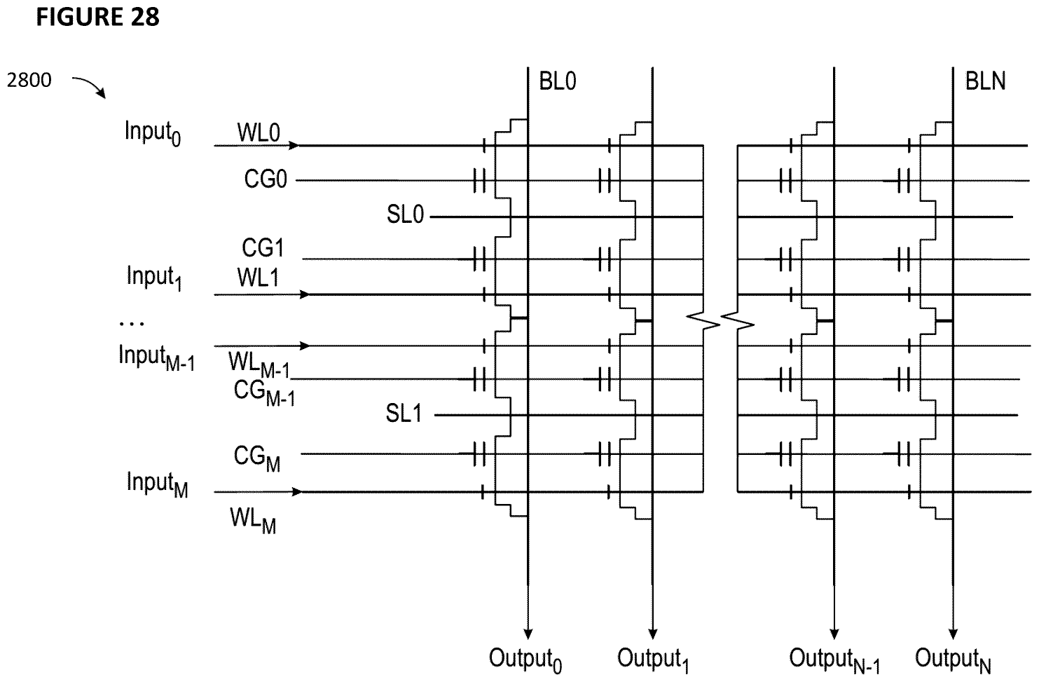

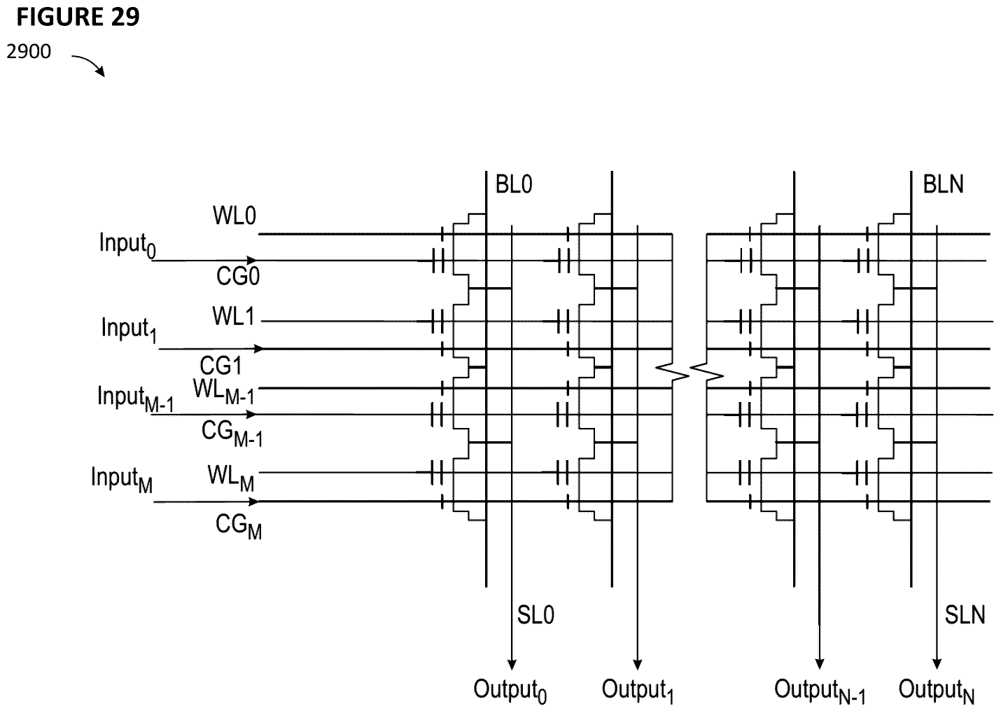

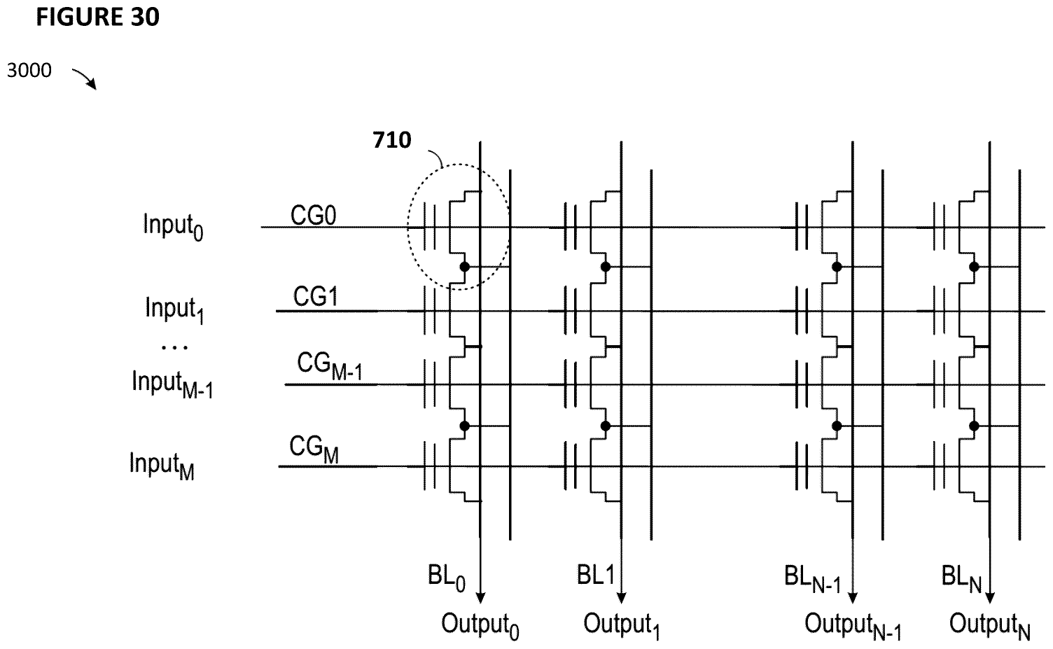

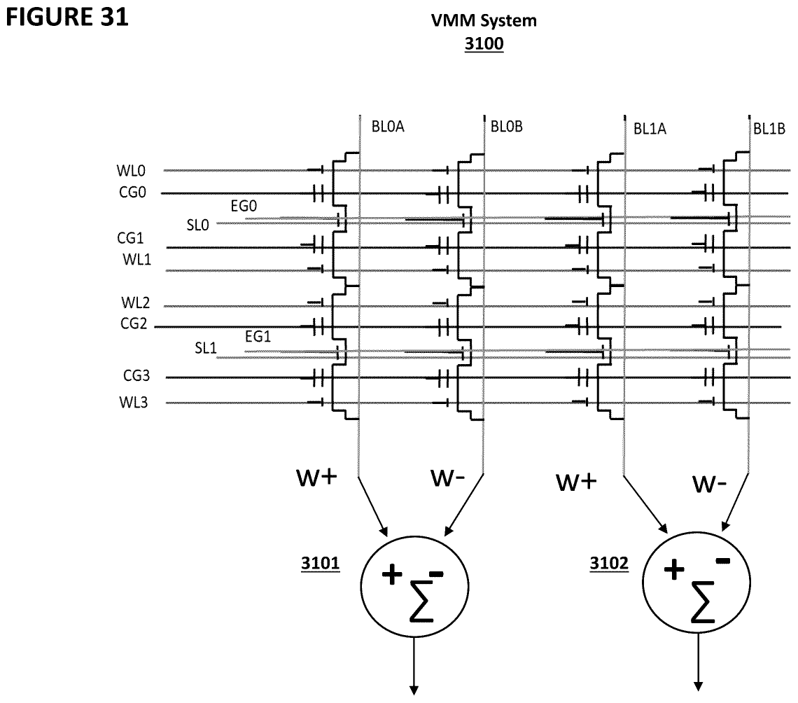

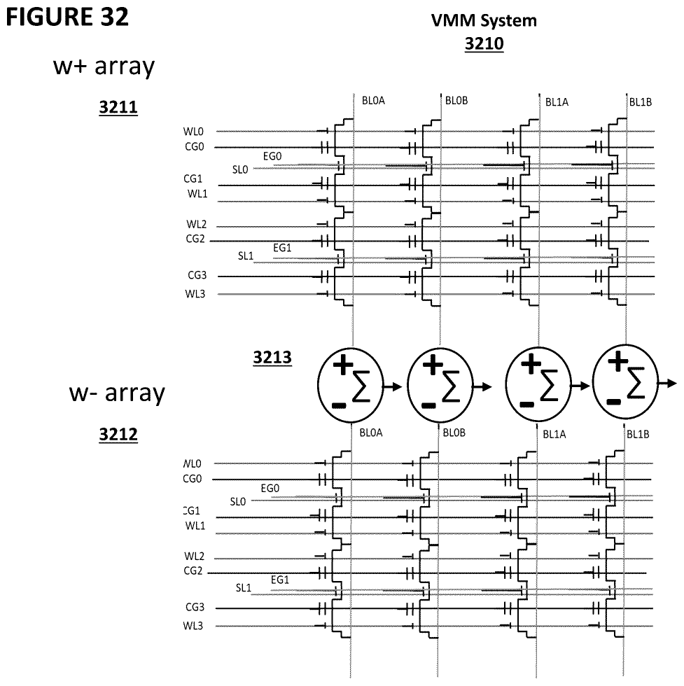

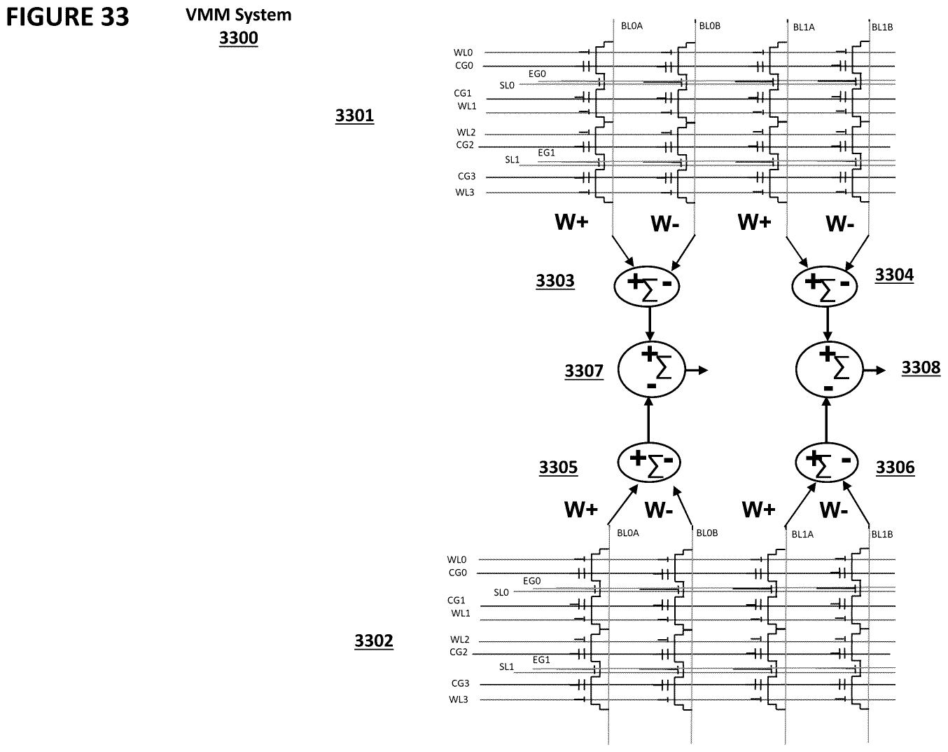

VMM array 3401 comprises an array of non-volatile memory cells arranges in rows and columns. In one example, the memory cells of VMM array 3401 comprise split-gate flash memory cells such as cells based on the design of memory cell 210, 310, or 410 in FIGS. 2, 3, and 4, respectively. In another example, the memory cells of VMM array 3401 comprise stacked-gate flash memory cells such as cells based on the design of memory cell 510 in FIG. 5.

The input circuit 3406 may include circuits such as a DAC (digital to analog converter), DPC (digital to pulses converter, digital to time modulated pulse converter), AAC (analog to analog converter, such as a current to voltage converter, logarithmic converter), PAC (pulse to analog level converter), or any other type of converters. The input circuit 3406 may implement one or more of normalization, linear or non-linear up/down scaling functions, or arithmetic functions. The input circuit 3406 may implement a temperature compensation function for input levels. The input circuit 3406 may implement an activation function such as ReLU or sigmoid. Input circuit 3406 may store digital activation data to be applied as, or combined with, an input signal during a program or read operation. The digital activation data can be stored in registers. Input circuit 3406 may comprise circuits to drive the array terminals, such as CG, WL, EG, and SL lines, which may include sample-and-hold circuits and buffers. A DAC can be used to convert digital activation data into an analog input voltage to be applied to the array.

The output circuit 3407 may include circuits such as an ITV (current-to-voltage circuit), ADC (analog to digital converter, to convert neuron analog output to digital bits), AAC (analog to analog converter, such as a current to voltage converter, logarithmic converter), APC (analog to pulse(s) converter, analog to time modulated pulse converter), or any other type of converters. The output circuit 3407 may convert array outputs into activation data. The output circuit 3407 may implement an activation function such as rectified linear activation function (ReLU) or sigmoid. The output circuit 3407 may implement one or more of statistic normalization, regularization, up/down scaling/gain functions, statistical rounding, or arithmetic functions (e.g., add, subtract, divide, multiply, shift, log) for neuron outputs. The output circuit 3407 may implement a temperature compensation function for neuron outputs or array outputs (such as bitline output) so as to keep power consumption of the array approximately constant or to improve precision of the array (neuron) outputs such as by keeping the IV slope approximately the same over temperature. The output circuit 3407 may comprise registers for storing output data.

In the examples discussed below, parameters of input circuit 3406 and output circuit 3407 may be configured depending on the type of neural network being implemented (for example, an MLP, CNN, RNN, or other type of network), the nature of the layer being implemented (for example, the first layer, a middle layer, or the last layer), on neural CNN operation being performed (for example, depthwise, 1D, or 2D), on the filter size or kernel size (for example, 3×3, 1×1, 7×7, or other size), on the channel depth (for example, 32, 64, 128, or another size).

Within output circuit 3407, ITVs can be configured per network layer to receive different input ranges and produce a constant array output which is used by the ADC to produce, for example, an 8-bit output. A resistor-based ITV (R-ITV) can be adjusted by changing one or more resistor values. A capacitor-based ITV (C-ITV) can be adjusted by changing one or more capacitor values or the integration time. ADCs can be configured per network layer to receive different input ranges from the ITV and produce a constant resolution such as an 8-bit output, A current mirror also can be used to mirror the array output with an adjustable ratio, Adjusting ITVs, ADCs, and current mirrors make it possible to implement a wide range of VMM outputs.

### Input Circuits

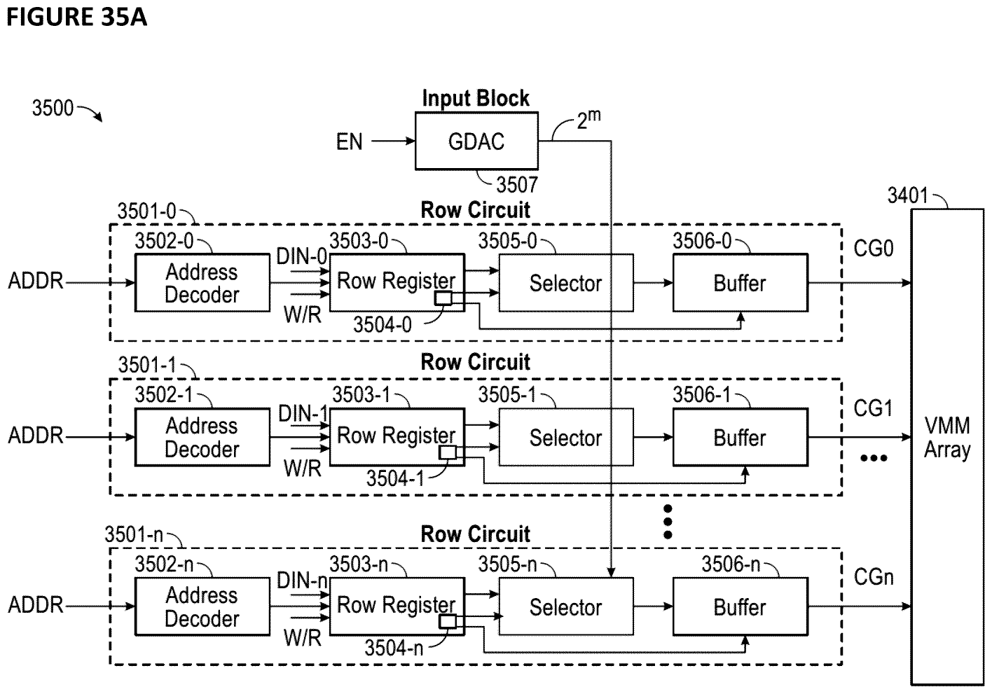

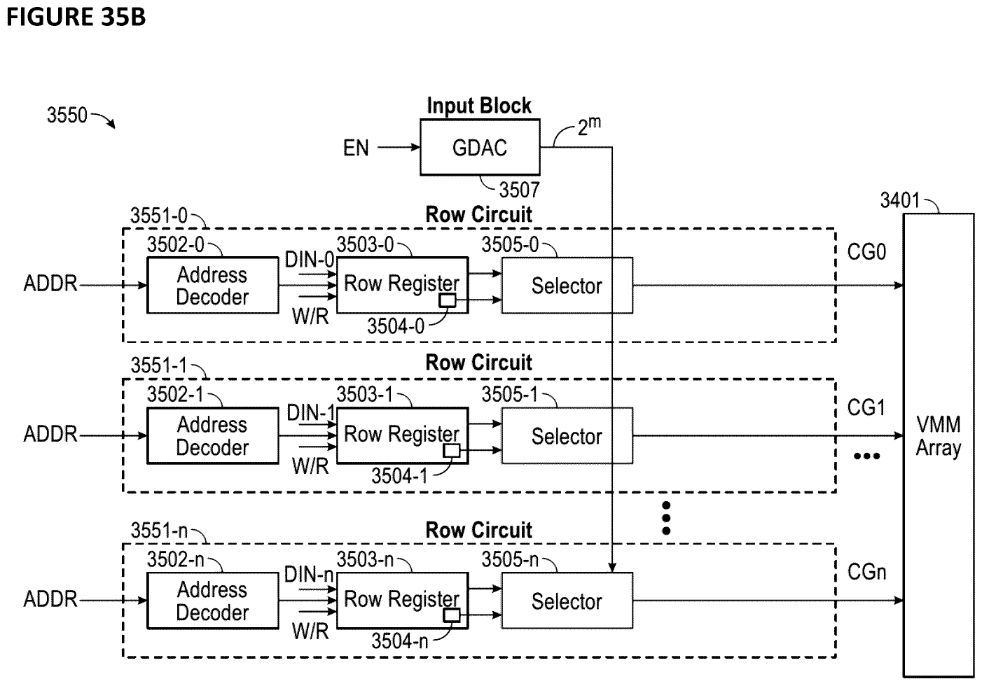

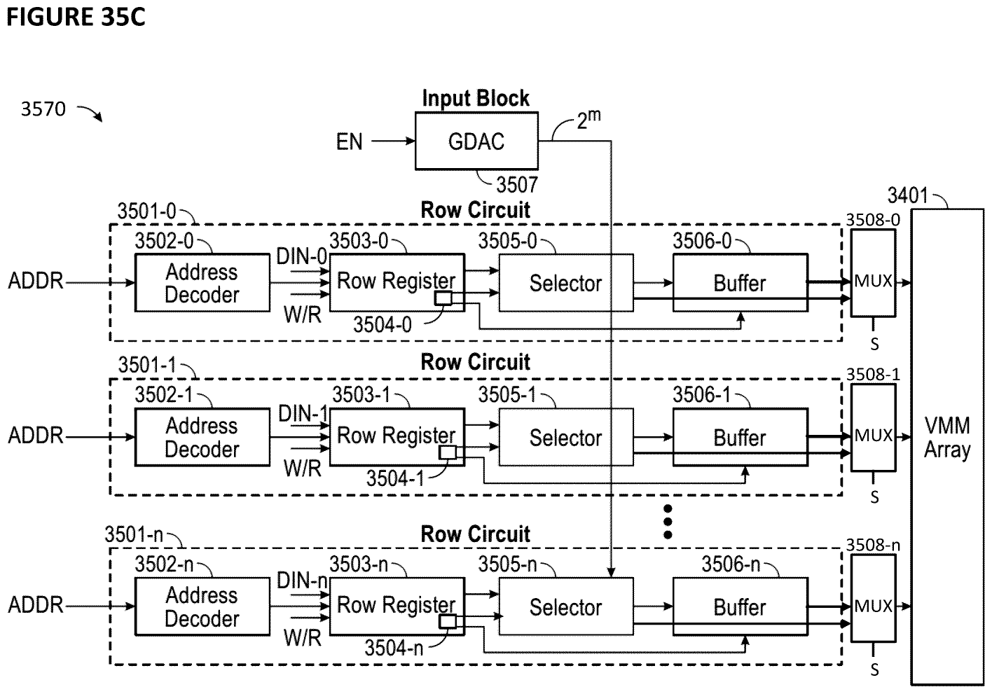

FIGS. 35A, 35B, 35C, 36A, 36B, 37A, 37B, 37C, 38A, and 38B depict examples of components that can be used in input circuit 3406 of FIG. 34 for purposes of applying input values to lines of VMM array 3401 during a read operation, where the input values will be multiplied by weights stored in cells of VMM array 3401 and each column of VMM array 3401 will generate an output current representing a sum of the products of each cell in the column multiplied by the input value received by that cell.

FIG. 35A depicts input block 3500. Input block 3500 comprises row circuits 3501-0, 3501-1, . . . , 3501-n, and global digital-to-analog converter (GDAC) 3507. VMM array 3401 is shown for clarity, but VMM array 3401 is not part of input block 3500. Input block 3500 is an example implementation of input circuit 3406 in FIG. 34.

Row circuit 3501-0 is an input circuit that generates, and applies, output CG0 to the control gate line of row 0 of non-volatile memory cells in VMM array 3401; row circuit 3501-1 is an input circuit that generates, and applies, output CG1 to the control gate line of row 1 of non-volatile memory cells in VMM array 3401; row circuit 3501-n is an input circuit that generates, and applies, output CGn to the control gate line of row n of non-volatile memory cells in VMM array 3401; and all other row circuits 3501 have the same role as to an associated row in VMM array 3401.

Row circuit 3501-0 comprises address decoder 3502-0, row register 3503-0, tag bit 3504-0, selector 3505-0, and buffer 3506-0. Similarly, row circuit 3501-1 comprises address decoder 3502-1, row register 3503-1, tag bit 3504-1, selector 3505-1, and buffer 3506-1; row circuit 3501-n comprises address decoder 3502-n, row register 3503-n, tag bit 3504-n, selector 3505-n, and buffer 3506-n; and all other row circuits 3501 have the same structure.

Each row circuit 3501 operates in the same manner. The load and read operations will be described as to row circuit 3501-0 but it is to be understood that this explanation applies to all other row circuits 3501 as well.

During a load operation, the W/R port on row register 3503-0 receives a value indicating a write operation (e.g., “0”) and row register 3503-0 is loaded with input data comprising m bits of data. For example, m might be 8, 16, 32, 64, 128, 256, or another other number. The input data to be loaded can be activation data or input data such as from an object or image that is to be classified or recognized by a neural network application. Address decoder 3502-0 receives an address, ADDR. If ADDR matches the address associated with row 0, address decoder 3502-0 asserts its output signal, which is provided to row register 3503-0. Row register 3503-0, in response to the asserted output signal of address decoder 3502-0, performs a load operation and stores the received data-in, DIN-0. The loaded data is used in a subsequent read or verify operation.

Row register 3503-0 also stores tag bit 3504-0, which tag bit 3504-0 can be used to enable or disable row 0, such as by disabling the output of selector 3505-0 or buffer 3506-0, regardless of whether the row is selected or not selected by address decoder 3502. For example, if tag bit 3504-0 has a certain value (e.g., “1”), the activation data in row register 3503-0 will be output when ADDR indicates that row 0 is selected. If tag bit 3504-0 has a different value (e.g., “0”), the activation data in row register 3503-0 will not be output because, for example, the tag bit value will disable the output of row register 3503-0, selector 3505-0 (for example, by serving as an input to an enable port), or buffer 3506-0 (for example, by serving as an input to an enable port), and a default value (e.g., “0”) will instead be output even when ADDR indicates that row 0 is selected. Tag bits 3504 can be useful, for example, to save power when a controller (not shown) determines that a read operation can be skipped. When row register 3503-0 is not disabled by tag bit 3504-0, it will output the data that was stored in it during the load operation when address decoder 3502-2 asserts its output in response to receiving the address ADDR that corresponds to row 0.

During a read or verify operation, address decoder 3502-0 receives an address, ADDR. If ADDR matches the address associated with row 0, address decoder 3502-0 asserts its output signal, which is provided to row register 3503-0. The W/R port on row register 3503-0 receives a value indicating a read operation (e.g., “1”) and row register 3503-0, in response to the asserted output signal of address decoder 3502-0, outputs its stored data, DIN-0 if its tag bit 3504-0 is a value (e.g., “1”) that enables the output of data.

GDAC 3507 receives an enable signal, EN, and when enabled, outputs 2″ different analog voltages on 2^{m} different output lines, where the 2″ different analog voltages represent the set of possible analog voltages that can be applied to a control gate line in VMM array 3401. Selector 3505 receives a value from row register 3503-0 (which can be “0” if ADDR is not the address corresponding to row 0, if tag bit 3504-0 was a value that does not enable the output of data, or if the stored activation data in row register 3503-0 is “0”; and which otherwise will be the value stored in row register 3503-0). Selector 3505-0 receives all 2m lines from GDAC 3507 and selects a particular line based on the m bit value received from row register 3503-0. The analog voltage from the selected line from GDAC 3507 is then provided to buffer 3506-0, which will then provide a buffered version of the received analog voltage (i.e., the buffered version of the received analog voltage will not substantially vary based on the input impedance or capacitance of VMM array 3401) to the control gate line CG0 of VMM array 3401.

FIG. 35B depicts input block 3550. Input block 3550 is identical to input block 3500 in FIG. 35A except that buffers 3506 have been removed. Input block 3550 comprises row circuits 3551-0, 3551-1, . . . , 3551-n, and GDAC 3507. VMM array 3401 is shown for clarity, but VMM array 3401 is not part of input block 3550. Input block 3550 is an example implementation of input circuit 3406 in FIG. 34.

Row circuit 3551-0 is an input circuit that generates, and applies, output CG0 to the control gate line of row 0 of non-volatile memory cells in VMM array 3401; row circuit 3551-1 is an input circuit that applies output CG1 to the control gate line of row 1 of non-volatile memory cells in VMM array 3401; row circuit 3551-n is an input circuit that applies output CGn to the control gate line of row n of non-volatile memory cells in VMM array 3401; and all other row circuits 3551 have the same role as to an associated row in VMM array 3401.

Row circuit 3551-0 comprises address decoder 3502-0, row register 3503-0, tag bit 3504-0, and selector 3505-0. Similarly, row circuit 3551-1 comprises address decoder 3502-1, row register 3503-1, tag bit 3504-1, and selector 3505-1; row circuit 3551-n comprises address decoder 3502-n, row register 3503-n, tag bit 3504-n, and selector 3505-n; and all other row circuits 3551 have the same structure.

Each row circuit 3551 operates in the same manner as row circuits 3501 in FIG. 35A except that during a read or verify operation, selectors 3505 apply the selected analog voltages directly to their associated control gate lines in VMM array 3401 without the use of a buffer, which saves space compared to the design of FIG. 35A with a possible downside of signal attenuation due to the lack of a buffer.

FIG. 35C depicts input block 3570. Input block 3570 is identical to input block 3500 in FIG. 35A with the addition of multiplexors 3508-0, 3508-1, . . . , 3508-n. Each multiplexor 3508 receives a first input from buffer 3506 of the same row and a second input from selector 3505 of the same row. Multiplexor 3508 receives a select signal, S, which outputs the first input when S=0 and the second input when S=1, where the output of multiplexor 3507 is applied to the associated row in VMM array 3401. The purpose of multiplexor 3508 is to provide an easy way to configure the system to utilize buffer 3506 in one mode and to not utilize buffer 3506 in another mode. Using buffer 3506 speeds up the read process but uses more power compared to the situation where buffer 3506 is not used. Examples of the difference in the time required to apply inputs to VMM array 3401 using buffer 3506 and not using buffer 3506 are shown in Table No. 9. Hence, different modes of row operation, which will be referred to herein as X-modes, are used depending on the number of rows to be enabled. The X-mode can be set by a set of configuration bits, X-mode[0:m]. For example, if 16 different modes are desired, X-mode can comprise four bits, X-mode[0:3], and different modes can be used when different numbers of rows are to be enabled, such as 1-16, 17-32, 33-64, 65-128, 129-256, 257-512, and 513-1024 rows. The control and timing circuitry (not shown) are adjusted automatically for each mode.

TABLE NO 9
Time for Applying Inputs to VMM Array
3401 With and Without Buffer 3506

| | Read Time Without | Read Time With |
|---|---|---|
| Number of Rows | Buffer (ns) | Buffer (ns) |
| 1 | 221 | 94 |
| 16 | 384 | 115 |
| 32 | 553 | 92 |
| 64 | 907 | 109 |
| 128 | 1613 | 118 |
| 256 | 3059 | 150 |
| 640 | 7368 | 193 |
| 1280 | 14819 | 413 |

Optionally, for input blocks 3500, 3550, and 3570 in FIGS. 35A, 35B, and 35C, respectively, a staggered row enable method can be used in which a subset of the row circuits 3501 and 3551 are enabled at any particular time to reduce power disruption, as might occur due to a power glitch, or to reduce the GDAC settling time. For example, during a first period, a first subset of the row circuits can be enabled, and during a second period, a second subset of the row circuits can be enabled.

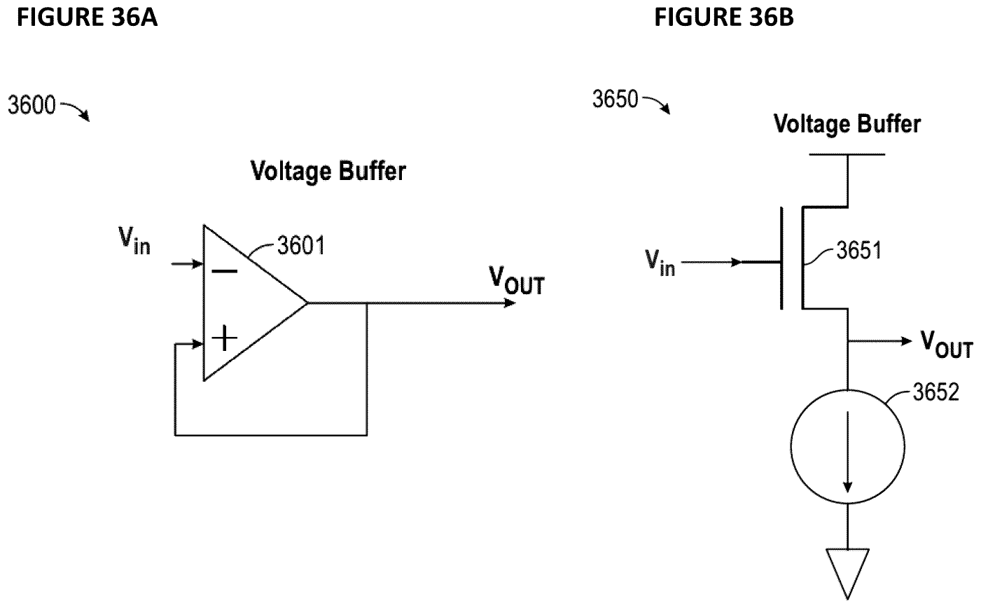

FIGS. 36A and 36B depict voltage buffers that can be used for buffers 3506 in FIGS. 35A and 35C.

FIG. 36A depicts voltage buffer 3600. Voltage buffer 3600 comprises operational amplifier 3601, which comprises an inverting terminal, a non-inverting terminal, and an output terminal. The inverting input terminal receives a voltage, VIN. The output terminal is coupled to the non-inverting input terminal and outputs VOUT. Voltage buffer 3600 provides voltage VOUT, which will remain substantially steady even as an attached load changes. Voltage buffer 3600 can be used to provide the buffered version of the received analog voltage, or the reference voltage, for any of the circuits described herein.

FIG. 36B depicts another voltage buffer 3650 configured as a source follower buffer, meaning the source voltage follows the gate voltage. Voltage buffer 3650 comprises transistor 3651 and current source 3652 and receives an input voltage, VIN, on a gate of transistor 3651 and provides an output voltage, VOUT, at the source of transistor 3651, which output voltage VOUT is proportional to VIN−VTN (where VTN is the threshold voltage of transistor 3851). Specifically, VOUT=VIN−VTN−sqrt(I/(0.5*u*Cox*W/L)), where Cox is the gate oxide capacitance per unit area, u is mobility, W is the width of transistor 3651, and L is the length of transistor 3651. Voltage buffer 3650 can be used to provide the buffered version of the received analog voltage, or the reference voltage, for any of the circuits described herein.

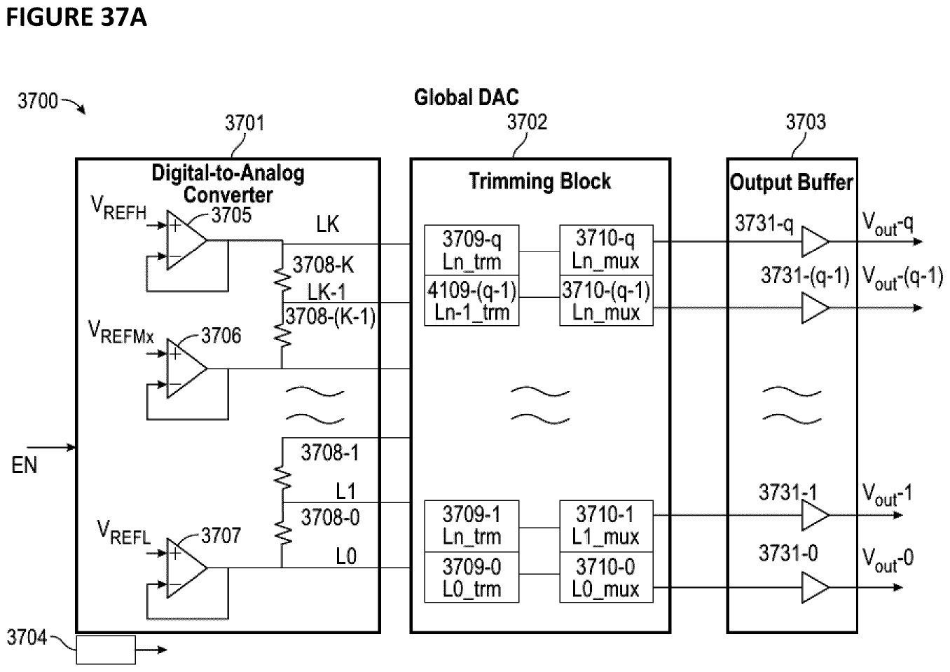

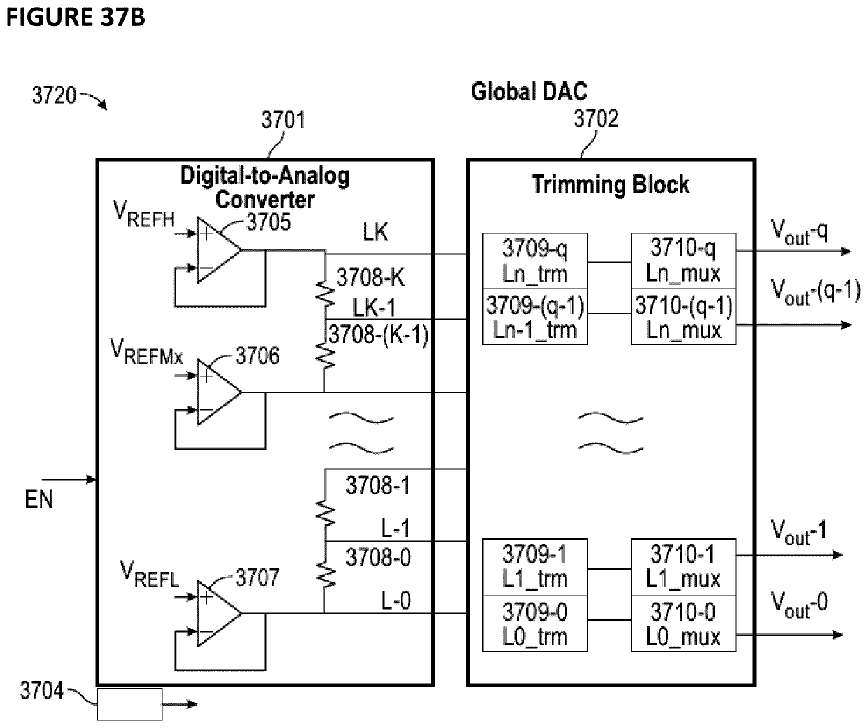

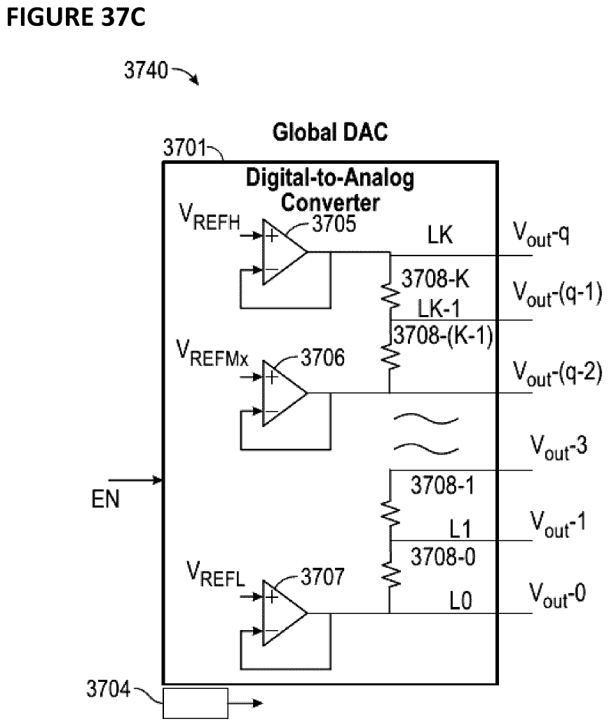

FIG. 37A depicts global digital-to-analog converter 3700, which can be used as GDAC 3507 in FIGS. 35A, 35B, and 35C. Global digital-to-analog converter 3700 comprises digital-to-analog converter 3701, trimming block 3702, and output buffer 3703. Control logic 3704 controls the operation of global digital-to-analog converter 3700, such as by enabling various blocks using enable signals (e.g., EN), providing control signals to multiplexors, and generating other control signals.

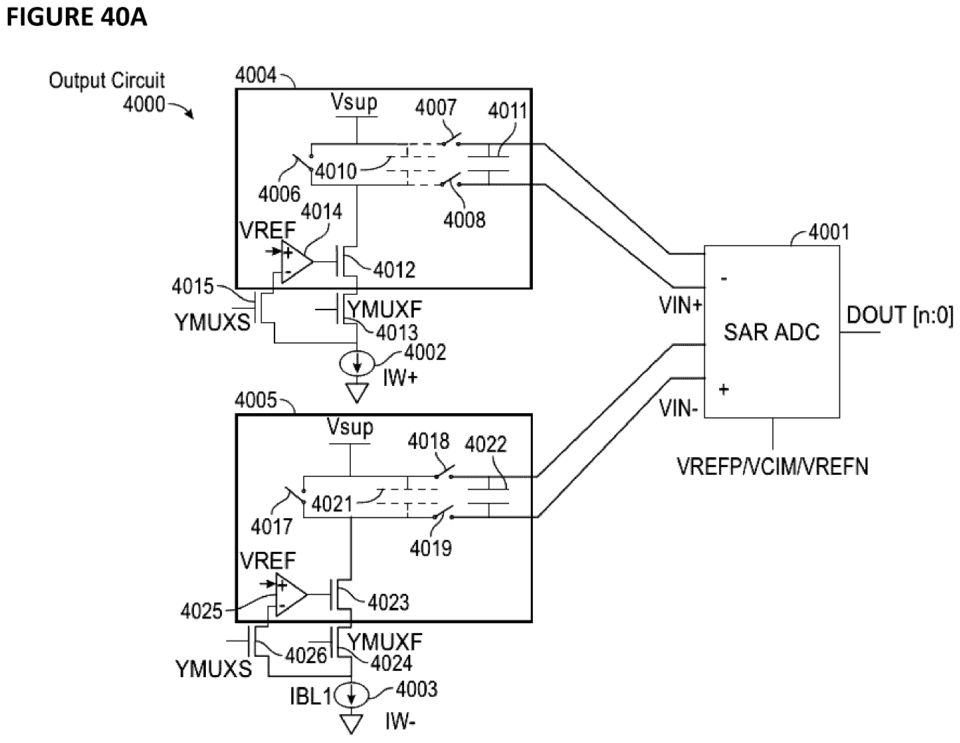

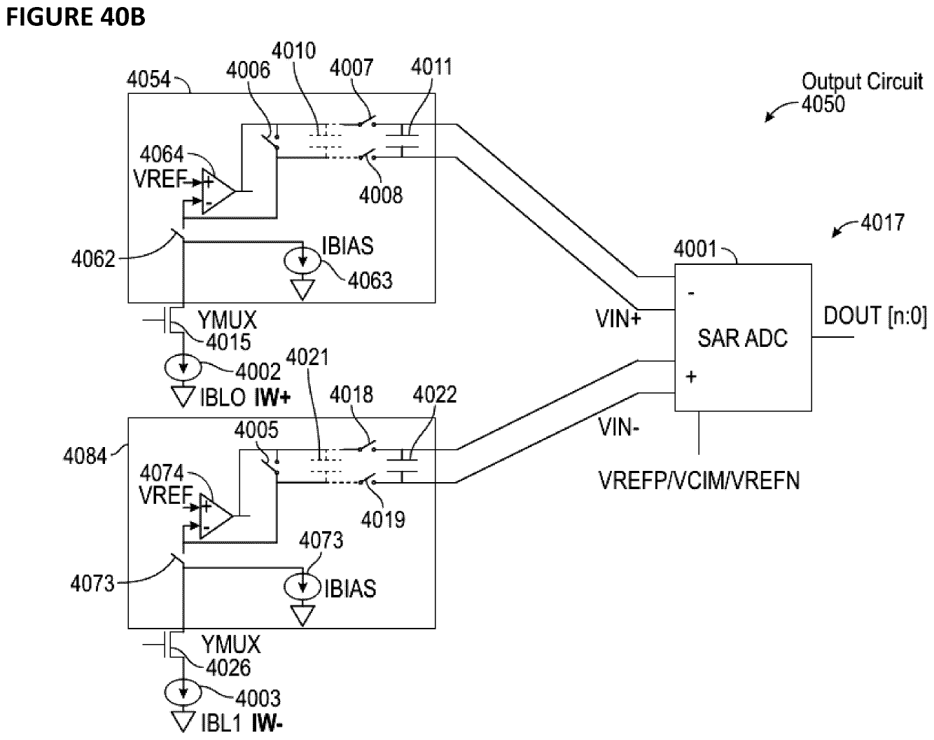

DAC 3701 receives a high reference voltage (VREFH), a medium reference voltage (VREFMx), and a low reference voltage, VREFL, provided to voltage buffers 3705, 3706, and 3707, respectively. Reference voltages VREFH/VREFM/VREFL are generated by a reference circuit such reference voltage generators 4020 and 4040 in FIGS. 40B and 40C. The values of reference voltages VREFH, VREFM, VREFL are determined in response to the maximum current level, medium current level, and low current level corresponding to the operation cell current range of VMM array 3401, for example, from 0-100 nA. Additional other reference voltages can be used, such as reference voltages with values between VREFL and VREFM and between VREFM and VREFH.

DAC 3701 comprises a voltage ladder comprising a plurality of resistors 3708-0, 3708-1, . . . , 3708-(k−1), 3708-k that are used to generate a range of voltages (L0, L1, . . . , L(k−1), Lk) between VREFH and VREFMx and between VREFMx and VREFL, optionally according to a linear function, a logarithmic function or a customized logarithmic function (e.g., where the memory cell operates in the sub-threshold region). For example, the top node of the top resistor 3708-k in the voltage ladder will have a voltage Lk equal to VREFH, and the bottom node of the bottom resistor 3708-0 in the voltage ladder will have a voltage L0 equal to VREFL, with intermediate nodes having voltages between VREFH and VREFL based on the voltage drop across resistors above and below the node. The voltage ladder thereby generates a plurality of voltage levels (L0, . . . , Lk) (for example, k might be 4095), which are used when it is desired to provide a voltage to a VMM array to cause the non-volatile memory cells of the VMM array to operate in linear mode or sub-threshold mode. VREFM can be chosen so that DAC 3701 simulates cell behavior.

Trimming block 3702 receives q+1 voltages from digital-to-analog converter. Trimming block 3702 comprises sub blocks 3709-0, 3709-1, . . . , 3709-(q−1), 3709-q and multiplexors 3710-0, 3710-1, . . . , 3710-(q−1), and 3710-q. Thus, trimming block 3702 comprises (q+1) trim blocks 3709 and (q+1) multiplexors 3710. Trimming block 3702 performs local trimming on each of the q+1 voltage levels. This may be useful, for example, when the non-volatile memory cells in the array are operating in the sub-threshold region. This is desirable to achieve a good matching I-V slope for the non-volatile memory cells in the VMM array over temperature in sub threshold region or linear region.

By adjusting reference voltages VREFL, VREFM, and VREFH, the k+1 levels are adjusted as well. This is, for example, to match the output range of this input block with an input range of the memory cells. This is also for temperature compensation by adjusting (such as shifting lower at high temperature and higher at lower temperature) the reference levels VREFL and VREFH to match that of the gate bias of the memory cells over temperature. Further individual voltage level adjustment and temperature compensation is done by trimming circuits of trimming block 3702.

The output from multiplexors 3710 is provided to output buffer 3703, which provides output voltages VOUT-0 to VOUT-q, where (q+1)=2m in FIGS. 35A, 35B, 36A, 36B, and 38. For example, if m=4, (q+1)=16, meaning that global DAC 3700 will generate 16 different voltage outputs. Output buffer 3703 comprises buffers 3731-0, 3731-1, . . . , 3731-(q−1), 3731-q.

FIG. 37B depicts global digital-to-analog converter 3720, which can be used as GDAC 3507 in FIGS. 35A, 35B, and 35C. Global digital-to-analog converter 3720 is identical to global digital-to-analog converter and row decoder 3700 in FIG. 37B except that output buffer 3703 has been removed, and the output of one or more selected multiplexors 3710 is provided as the output voltages VOUT-0 to VOUT-q, where (q+1)=2^{m} in FIGS. 35A, 35B, 36A, 36B, and 38. Similarly, additional other reference voltages can be used such as with values between VREFL and VREFM and between VREFM and VREFH.

FIG. 37C depicts global digital-to-analog converter 3740, which can be used as GDAC 3507 in FIGS. 35A, 35B, and 35C. Global digital-to-analog converter 3740 is identical to global digital-to-analog converter and row decoder 3720 in FIG. 37B except that trimming block 3702 has been removed, and the nodes in the voltage ladder provide output voltages VOUT-0 to VOUT-q, where (q+1)=2^{m} in FIGS. 35A, 35B, 36A, 36B, and 38. Similarly, additional other reference voltages can be used such as with values between VREFL and VREFM and between VREFM and VREFH.

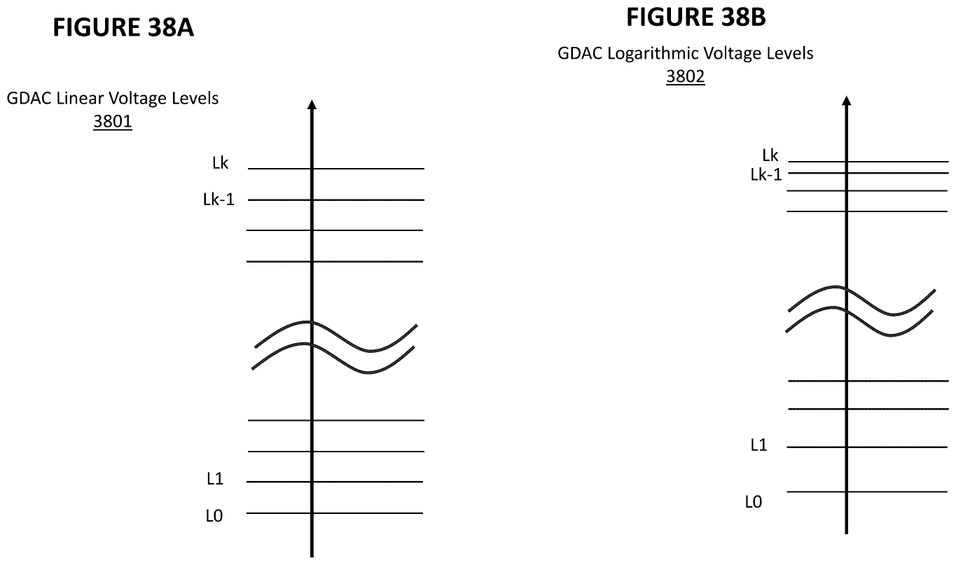

FIG. 38A depicts GDAC linear voltage levels 3801, which comprise voltage levels L0, L1, . . . , Lk−1, and Lk generated by the voltage ladder in digital-to-analog converter 3701 in FIGS. 37A, 37B, and 37C, where the voltage levels are spaced according to a linear function determined by the resistance values of resistors 3708-0, 3708-1, . . . , 3708-(k−1), and 3708-k.

FIG. 38B depicts GDAC non-linear voltage levels 3802, which comprise voltage levels L0, L1, . . . , Lk−1, and Lk generated by the voltage ladder in digital-to-analog converter 4101 in FIGS. 37A, 37B, and 37C, where the voltage levels are spaced according to a logarithmic function determined by resistance values of resistors 4108-0, 4108-1, . . . , 4108-(k−1), and 4108-k. The logarithmic function can be derived from the sub threshold equation of the memory cell.

### Output Circuits

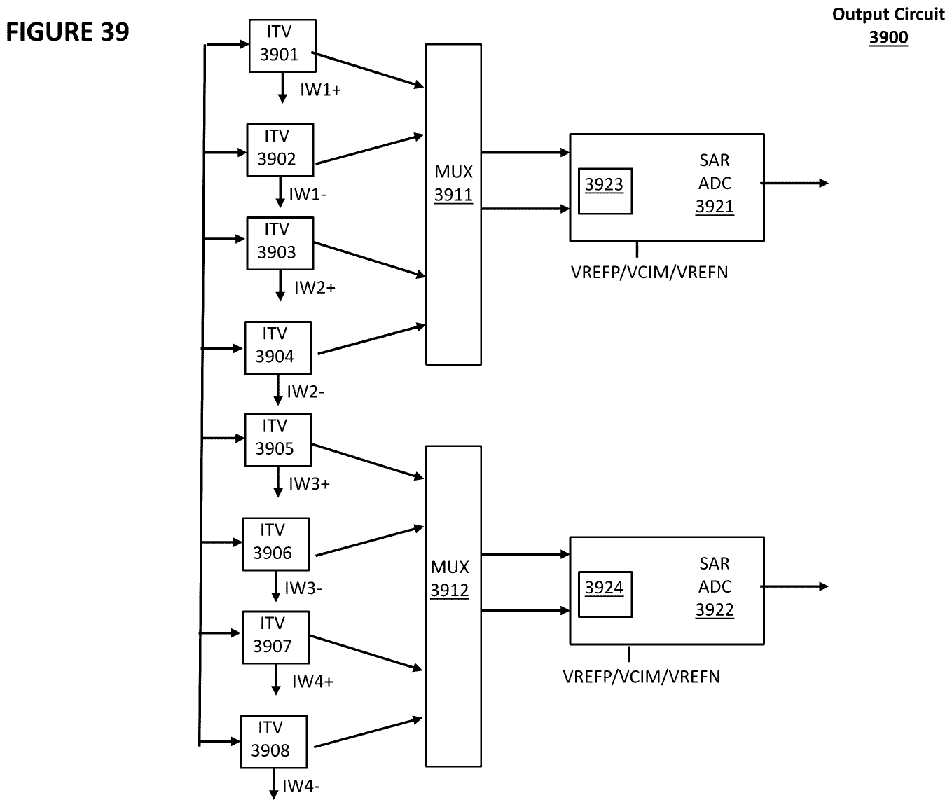

FIGS. 39-43 depict examples of components that can be used in output circuit 3407 of FIG. 34 for receiving and modifying output current received from each column of VMM array 3401, where the output current represents a sum of the products of each cell in the column multiplied by the input value received by that cell during a read operation.

FIG. 39 depicts output circuit 3900, which form part of output circuit 3407 in FIG. 34 to operate on two columns. It is to be understood that a plurality of instantiations of output circuit 3900 can be used to cover all columns in VMM array 3401.

Output circuit 3900 comprises configurable current-to-voltage converters (Configurable ITVs) 3901, 3902, 3903, 3904, 3905, 3906, 3907, and 3908. Configurable ITV 3901 is coupled to bit line current IW1+ (a first current), configurable ITV 3902 is coupled to bit line current IW1− (a second current), configurable ITV 3903 is coupled to bit line current IW2+ (a third current), configurable ITV 3904 is coupled to bit line current IW2−°(a fourth current), configurable ITV 3905 is coupled to bit line current IW3+ (a fifth current), configurable ITV 3906 is coupled to bit line current IW3− (a sixth current), configurable ITV 3907 is coupled to bit line IW4+ (a seventh current), and configurable ITV 3908 is coupled to bit line current IW4− (an eighth current). Outputs from configurable ITVs 3901, 3902, 3903, and 3904 are provided as inputs to multiplexor 3911. Outputs from configurable ITVs 3905, 3906, 3907, and 3908 are provided as inputs to multiplexor 3912. The selected output from multiplexor 3911 is provided to SAR ADC 3921 (containing CDAC 3923). The selected output from multiplexor 3912 is provided to SAR ADC 3922 (containing CDAC 3924).

Configurable ITV's 3901, 3902, 3903, 3904, 3905, 3906, 3907, and 3908 each comprise a variable resistor block for generating voltages in response to a relatively higher current range, such as 5 to 25 μA, a variable capacitor block for generating voltages in response to a relatively lower current range, such as 0.25 to 5 μA, or both a variable resistor block and a variable capacitor block.

FIG. 40A depicts output circuit 4000, which can be used for two columns in output block 3407 in FIG. 34 and is an example that can be used in output circuit 3900 of FIG. 39 using adjustable capacitor-based ITVs. Output block 3407 can comprise multiple instantiations of output circuit 4000, where each instantiation is used with two columns in VMM array 3401, where one column contains a IW+ value and the other column contains a IW− value.

Output circuit 4000 is a differential circuit, meaning the circuit output is a function of two inputs. Output circuit 4000 comprises current-to-voltage converter (ITV) 4004 (a first current-to-voltage converter), ITV 4005 (a second current-to-voltage converter), differential input serial approximation register analog-to-digital converter (SAR ADC) 4001, transistors 4013, 4015, 4024, and 4026 (which form a portion of a column multiplexor, which couples a column in a first set of columns to ITV 4004 and couples a column in the second set of columns to ITV 4005), and current sources 4002 and 4003. Current source 4002 represents current drawn by a column in VMM array 3401 that is selected by the column multiplexor, where the column stores W+ values. Current source 4003 represents current drawn by a column in VMM array 3401 that is selected by the column multiplexor, where the column stores W− values. Output circuit 4000 receives current IW+ (a first current) and IW− (a second current) from two differential columns, W+ and W−, respectively, and outputs a digital output, DOUT, indicative of those currents, which is equivalent to W=W+−W−.

In one alternative, output circuit 4000 can be implemented as a single ended circuit, meaning that one ITV (4004 or 4005) and a single input ADC is used. In another alternative, a differential output can be achieved by using two sets of the ITVs and a single input ADC can be formed by combining the two results. In another alternative, a differential output can be achieved by performing time multiplexing and using the ITV and a single input ADC by combining the two results in time.

ITV 4004 comprises switches 4006, 4007, and 4008; integration capacitors 4010 and 4011; NMOS cascoding transistor 4012; and operational amplifier 4014. Prior to a read operation, switches 4006, 4007, and 4008 are closed, resulting in the top and bottom plates of integration capacitors 4010 and 4011 being charged to Vsup and VIN+ equal to Vsup. During an integration period, switch 4006 is opened. Current source 4002 draws current, resulting in the voltage of VIN+ (a first voltage) being pulled downward in proportion to the current drawn by current source 4002. That is, VIN+ will equal the initial value of VIN+ before the read operation minus a first discharge value due to the first current, IW+. After the integration period, the voltages across the capacitors 4010 and 4011 are sampled into the SAR ADC 4001. After this sampling period, the ADC will start to do conversion of this sampled voltages into digital output bits. In one example, the voltages on one or more of capacitor 4010 and capacitor 4011 are buffered before going to the SAR ADC 4001 In another example, capacitor 4011 is a capacitor in the binary capacitor array of the SAR ADC 4001 (that is, ITV 4004 and SAR ADC 4001 share a capacitor to save die space). In this case, after the integration period, switches 4007 and 4008 are opened, and SAR ADC 4001 starts the conversion of voltages on capacitor 4011 into digital output bits.

Similarly, ITV 4005 comprises switches 4017, 4018, and 4019; capacitors 4021 and 4022; NMOS cascoding transistor 4023; and operational amplifier 4025. Prior to a read operation, switches 4017, 4018, and 4019 are closed, resulting in the top and bottom plates of integration capacitors 4021 and 4022 being charged to Vsup and VIN− equal to Vsup. During an integration period, switch 4017 is opened. Current source 4003 will draw current, resulting in the voltage of VIN− (a second voltage) being pulled downward in proportion to the current drawn by current source 4003. That is, VIN− will equal the initial value of VIN− before the read operation minus a first discharge value due to the first current, IW−. Capacitors 4021 and 4022 are similar to capacitors 4010 and 4011 in the ITV 4004. Switches 4018 and 4019 are similar to switches 4007 and 4008 in ITV 4004. The operation of ITV 4005 is similar to that of ITV 4004 for the current IW−.

Bitline regulation circuit for the ITV 4004 includes the operational amplifier 4014, transistor 4012, and transistors 4013 and 4015 which are both turned on when a read operation is desired for the bit line IW+. This circuit imposes a fixed bias on a bitline during a read operation. Specifically, it imposes VREF, which is applied to the positive input terminal of operational amplifier 4014, on the bit line during a read operation irrespective of the magnitude of the current drawn by bit line IW+.

Similarly, bitline regulation circuit for the ITV 4005 includes the operational amplifier 4025, transistor 4023, and force and sense transistors 4024 and 4026 which are both turned on when a read operation is desired for the bit line IW−. This circuit imposes VREF, which is applied to the positive input terminal of operational amplifier 4025, on the bit line during a read operation irrespective of the magnitude of the current drawn by bit line IW+

SAR ADC 4001 receives differential voltages VIN+ and VIN− and reference voltages VADCREFH and VADCREFL and generates a digital output, DOUT[n:0], based on the difference between VIN+ and VIN−.

Notably, integration capacitors 4010 and 4021 will utilize significant die space since they will be relatively large. Optionally, integration capacitors 4011 and 4022 are re-used from the capacitor arrays of the SAR ADC 4001 to save area within the die. When the SAR ADC 4001 starts the conversion, switches 4007, 4008, 4018, and 4019 are opened.

FIG. 40B depicts output circuit 4050 which has the capacitors and the ADC circuit similar to those in FIG. 40A. The top circuit 4054 for the IW+ bitline current now has one ymux transistor 4015 which couples the bitline to switch 4062 which then couples to the negative terminal of an op-amp 4064. The output of the op-amp drives the top plate of the capacitors. The positive terminal of the op-amp 4064 receives a reference signal VREF. In addition, there optionally is a bias current IBIAS 4063 coupled to the bitline. The bias current is used to speed up the circuit. IBIAS 4063 is a constant fixed bias or a timed current bias such as one where the bias is only applied during an initial time period but not during the entire operation (which results in a pre-charge voltage on the bitline) and is released or disabled after the initial time period so that only the bitline current is active. The bottom circuit 4084 has similar elements as the top circuit 4054 for the IW− bitline current.

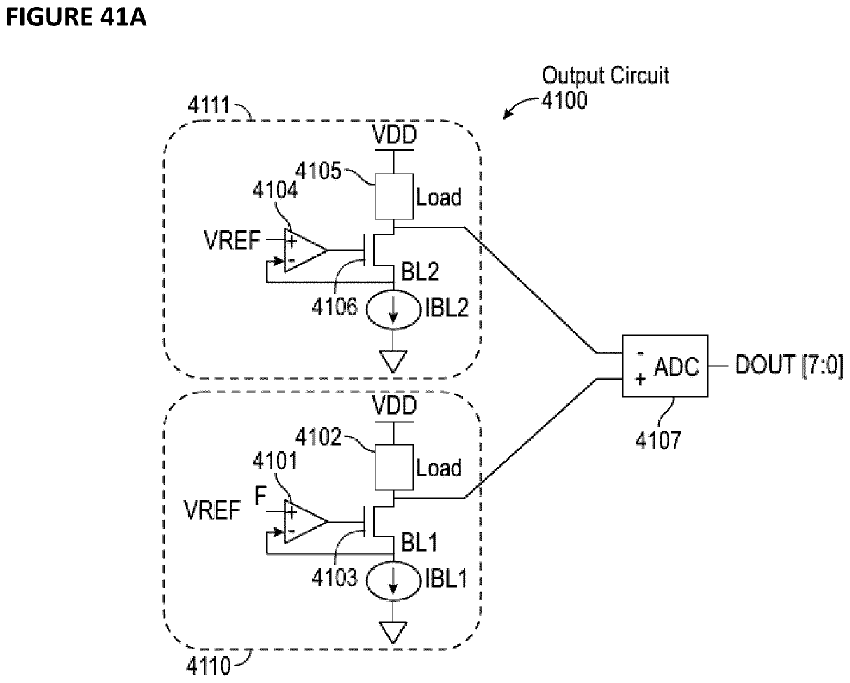

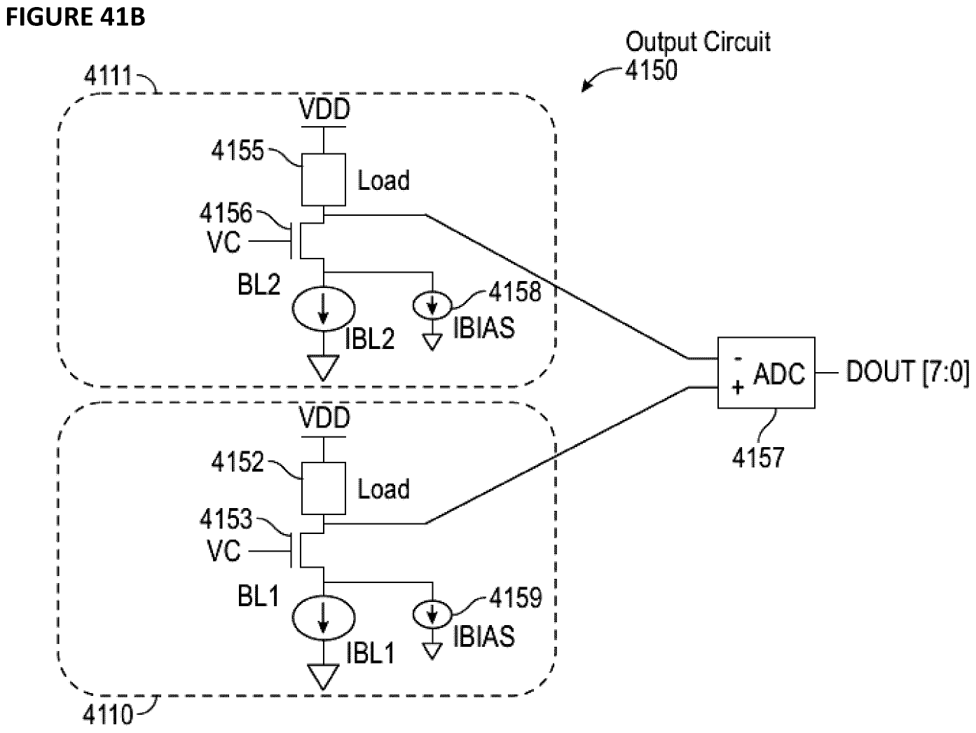

FIG. 41A depicts output circuit 4100, which can be used for two columns in output block 3407 in FIG. 34 and is an example that can be used in output circuit 3900 of FIG. 39 using resistor-based ITVs. Output circuit 4100 is used to read a value stored in differential memory cells coupled to a first bit line and a second bit line in an array of memory cells, where IBL1 is the current drawn by the first bit line coupled to a first column of cells in the array and IBL2 is the current drawn by the second bit line coupled to a second column of cells in the array and generate differential digital output bits by a differential ADC.

Read circuit 4100 comprises current-to-voltage converter 4110 (a first current-to-voltage converter), current-to-voltage converter 4111 (a second current-to-voltage converter), and differential ADC 4107 (which can be a SAR ADC or other type of ADC).

Current-to-voltage converter 4110 comprises operational amplifier 4101 (a first operational amplifier) (or an equivalent regulating circuit), load 4102 (a first load, which can comprise one or more resistors, capacitors, or transistors), and NMOS transistors 4103 (a first transistor). Load 4102 comprises a first terminal coupled to a voltage source VDD and a second terminal. NMOS transistor 4103 comprises a first terminal coupled to the second terminal of load 4102, a gate, and a second terminal coupled to the first bit line. Operational amplifier 4101 comprises an inverting input coupled to the first bit line, an inverting input coupled to VREF1 (a first reference voltage) and an output coupled to the gate of NMOS transistor 4103.

Current-to-voltage converter 4111 comprises operational amplifier 4104 (a second operation amplifier) (or an equivalent regulating circuit), load 4105 (a second load, which can comprise one or more resistors, capacitors, or transistors), and NMOS transistor 4106 (a second transistor). Load 4105 comprises a first terminal coupled to a voltage source VDD and a second terminal. NMOS transistor 4106 comprises a first terminal coupled to the second terminal of load 4105, a gate, and a second terminal coupled to the second bit line. Operational amplifier 4104 comprises an inverting input coupled to the second bit line, an inverting input coupled to VREF2 (a second reference voltage, which can be the same or different than VREF1) and an output coupled to the gate of NMOS transistor 4103.

As an example, using a 12.5 kΩ resistor for loads 4102 and 4105 will generate currents of approximately 25 uA into the terminals of NMOS transistors 4103 and 4106, respectively.

ADC 4107 comprises a first input coupled to the second terminal of the first load, a second input coupled to the second terminal of the second load, and an output to generate a set of output bits.

Thus, the non-inverting inputs of operational amplifiers 4101 and 4104 are each coupled to a reference voltage Vref, and the source of regulating transistors 4106 and 4103 are connected to the inverting input of operational amplifiers 4104 and 4101, respectively. The source voltage of transistors 4106 and 4103 are thus driven to be equal to VREF, meaning voltages of BL1 and BL2 coupled to the selected cells are driven to VREF voltage). Here, the voltages provided to the inverting and non-inverting terminals of ADC 4107 are referenced with respect to the supply voltage, VDD, and are the result of voltage drops from the supply voltage in amounts equal to the currents IBL2 and IBL1 through loads 4105 and 4102, respectively. The output of the ADC effectively implements W=W+−W−.

FIG. 41B depicts output circuit 4150 which is similar to the output circuit in FIG. 41A except there is no operational amplifier circuits and the transistors 4156 and 4153 have gates controlled by a voltage VC. In addition, there are two additional bias currents IBIAS 4158 and 4159 in bitlines BL2 (IW+) and BL1 (IW−) respectively. The bias currents are used to improve the speed of the circuit. The IBIAS 4158 and 4159 currents are constant fixed biases or timed current biases such as one where the bias is only applied during an initial time period (which results in a pre-charge voltage on the bitline) and is released or disabled after the initial time period. Due to differential output circuit structure, the two bias currents will cancel each other out. In one example, the circuits operate over two periods. In the first calibration period, the bitline current IBL1 and IB12 are disabled, and the circuit converts the differential currents on the two bitlines which now includes the two bias current 4158 and 4159, and any other leakage currents. The results will be stored. In the second period, the circuit converts the differential currents on the two bitlines which now includes the two bitline currents, IBL1 and IBL1, two bias current 4158 and 4159, and any other leakage currents. The result is then subtracted from the result of the first period. The additional bias currents and this operation method can be applied to other circuits described herein.

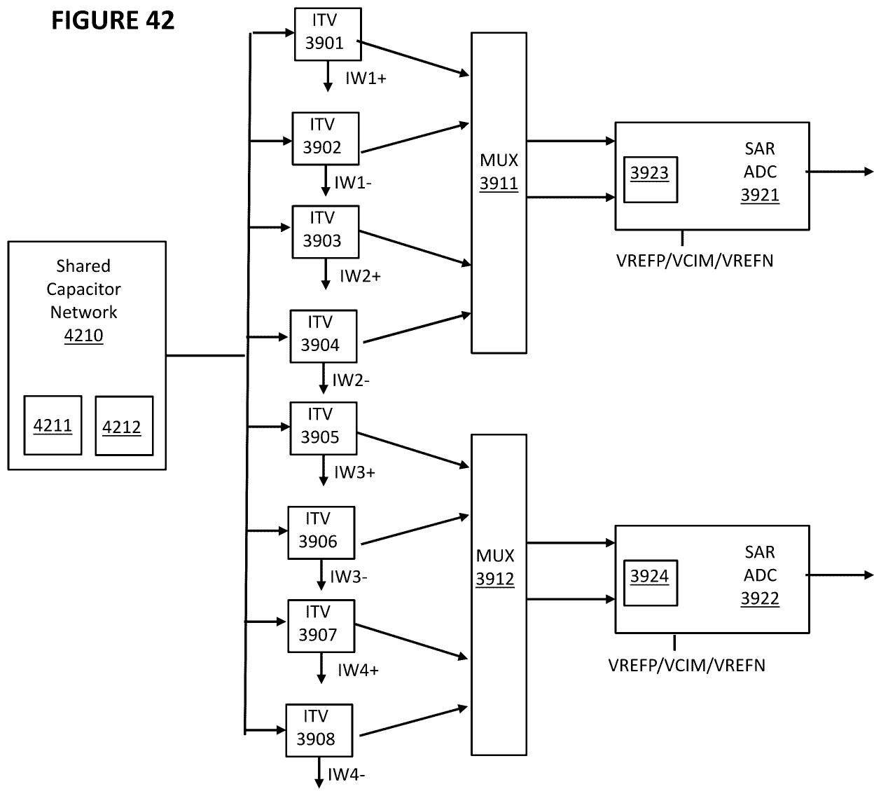

FIG. 42 depicts output circuit 4200, which is identical to output circuit 3900 in FIG. 39 with the addition of shared capacitor network 4210 that comprises shared capacitors 4211 and 4212 and a series of switches to selectively coupled shared capacitors 4211 and 4212 to ITVs 3901, 3902, 3903, 3904, 3905, 3906, 3907, and 3908. Shared capacitor network 4210 optionally can be used in place of separate capacitor blocks in each of ITVs 3901, 3902, 3903, 3904, 3905, 3906, 3907, and 3908 to reduce the amount of die space used for capacitors.

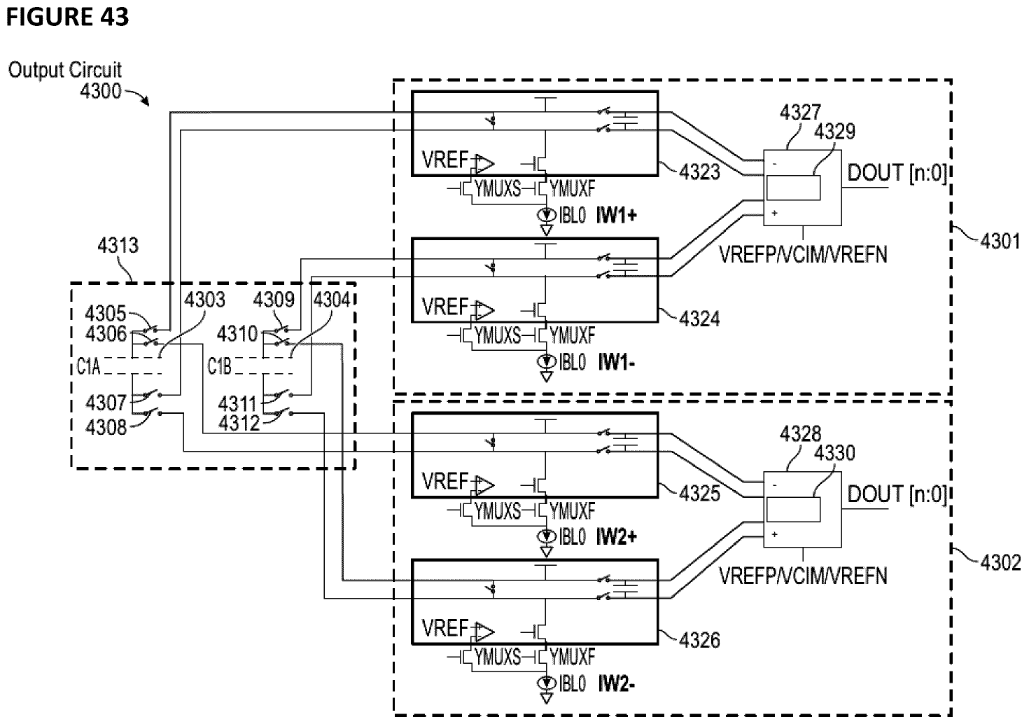

FIG. 43 depicts output circuit 4300, which can be used for four columns in output block 3407 in FIG. 34 and is an example that can be used in output circuit 4100 of FIG. 41 using adjustable capacitor-based ITVs. Output block 3407 can comprise multiple instantiations of output circuit 4300, where each instantiation is used with four columns in VMM array 3401, where the four columns contain two pairs of IW+ and IW− columns.

Output circuit 4300 comprises circuit 4301, circuit 4302, and shared capacitor network 4313. Circuits 4301 and 4302 each are identical to output circuit 4000 in FIG. 40 except that integration capacitors 4010 and 4021 in output circuit 4000 have been replaced by shared integration capacitors 4303 (a first integration capacitor) and 4304 (a second integration capacitor), respectively, in shared capacitor network 4313 with the addition of switches 4305, 4307, 4309, and 4311 used in shared capacitor network 4313 for circuit 4301; and switches 4306, 4308, 4310, and 4312 are used in shared capacitor network 4313 for circuit 4302. Circuit 4301 comprises ITV 4323 (a first current to voltage converter) coupled to IW1+ (a first current) and ITV 4324 (a second current to voltage converter) coupled to IW1− (a second current). Circuit 4302 comprises ITV 4325 (a third current to voltage converter) coupled to IW2+ (a third current) and ITV 4326 (a fourth current to voltage converter) coupled to IW2− (a fourth current). This design uses two fewer capacitors compared to using two instantiations of output circuit 3700 in FIG. 37.

ITV 4323 generates a first voltage and ITV 4324 generates a second voltage and are coupled to SAR ADC 4327 (a first SAR ADC) comprising CDAC 4329. ITV 4325 generates a third voltage and ITV 4326 generates a fourth voltage and are coupled to SAR ADC 4328 (a second SAR ADC) comprising CDAC 4330. During a read operation, the first voltage will be equal to an initial voltage (the voltage on that same node before the read operation) minus a first discharge value due to IW1+, the second voltage will be equal to an initial voltage (the voltage on that same node before the read operation) minus a second discharge value due to IW1−, the third voltage will be equal to an initial voltage (the voltage on that same node before the read operation) minus a third discharge value due to IW2+, and the fourth voltage will be equal to an initial voltage (the voltage on that same node before the read operation) minus a fourth discharge value due to IW2−.

Thus, shared integration capacitor 4303 (a first integration capacitor) is shared in a time-multiplexed manner by ITV 4323 and ITV 4326, and shared integration capacitor is shared in a time-multiplexed manner by ITV 4324 and ITV 4326.

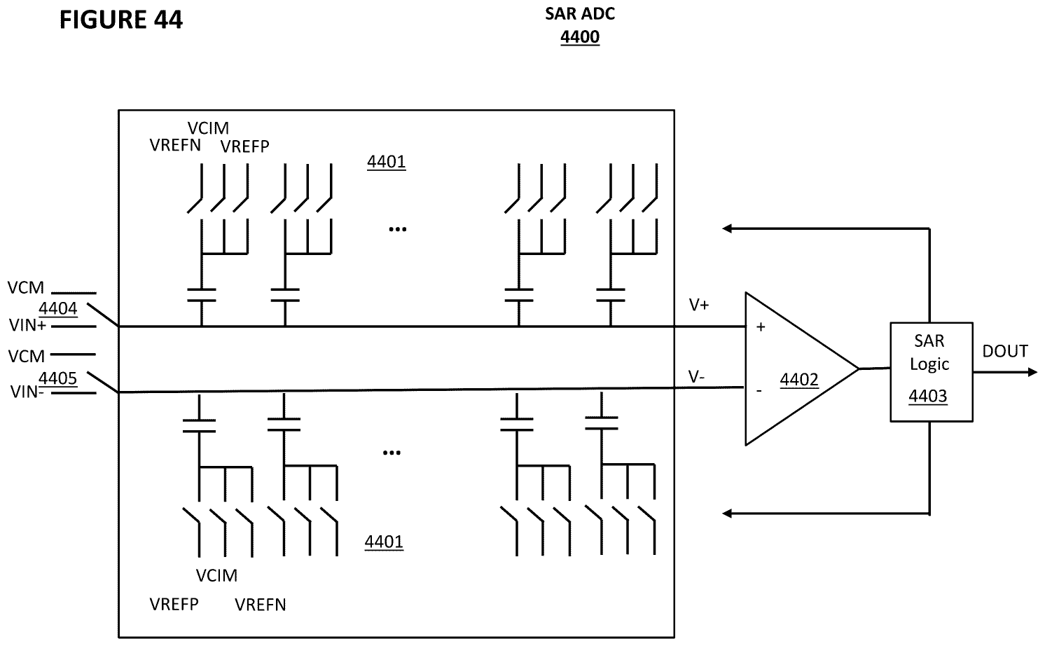

FIG. 44 depicts SAR ADC 4400 that is an example of an SAR ADC that can be used for SAR ADCs 3921 and 3922 in FIG. 39, SAR ADC 4001 in FIG. 40, ADC 4107 in FIG. 41, SAR ADCs 3921 and 3922 in FIG. 42, and SAR ADCs 4327 and 4328 in FIG. 43.

SAR ADC 4400 comprises CDAC 4401 (which is an example of CDACs 3923, 3924, 4329, and 4330 in FIGS. 39, 42, and 43), comparator 4402, SAR logic 4403, switch 4404, and switch 4405. Part or all of CDAC 4401 optionally, when not performing an operation in SAR ADC 4400, can be used as capacitors 4303 and 4304 in FIG. 43.

SAR ADC 4400 operates by first sampling the input voltages VIN+ and VIN− into the capacitor array (CDAC) 4401P and 4401N, respectively. SAR logic 4403 will successively convert the voltages into digital bits, starting with the most significant bit and ending with the least significant bit. For example, for an 8-bit ADC, B7 will be converted first and B0 will be converted last. Hence, there are 8 conversion clocks for an 8-bit ADC. For each conversion, the VIN+ will be compared against VIN−, and the comparison decision is used to switch the capacitors associated with the bit for the next bit comparison. Other examples of bit line regulators can use the same design of FIGS. 40A, 40B, 41, 42, and 43 with no operational amplifier, where a bias voltage is used in place of the op-amp, where the bias voltage can be fixed or variable in a way that adjusts to changes in PVT (process, voltage, or temperature).

As used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements there between.

What is claimed is:

1. A system comprising:
a vector-by-matrix multiplication array comprising non-volatile memory cells arranged into rows and columns; and
an output block coupled to the vector-by-matrix multiplication array to receive current from the columns of the vector-by-matrix multiplication array, the output block comprising:
a current-to-voltage converter to receive current from one or two columns and convert the current into a voltage, the current-to-voltage converter comprising one or more variable resistors configurable to adjust a range of possible values of the voltage; and
an analog-to-digital converter to convert the voltage into digital bits.

2. The system of claim 1, wherein the non-volatile memory cells are stacked-gate flash memory cells.

3. The system of claim 1, wherein the non-volatile memory cells are split-gate flash memory cells.

4. A system comprising:
a vector-by-matrix multiplication array comprising non-volatile memory cells arranged into rows and columns; and
an output block coupled to the vector-by-matrix multiplication array to receive current from the columns of the vector-by-matrix multiplication array, the output block comprising:
a current-to-voltage converter to receive current from one or two columns and convert the current into a voltage, the current-to-voltage converter comprising one or more variable capacitors configurable to adjust a range of possible values of the voltage; and
an analog-to-digital converter to convert the voltage into digital bits.

5. The system of claim 4, wherein the non-volatile memory cells are stacked-gate flash memory cells.

6. The system of claim 4, wherein the non-volatile memory cells are split-gate flash memory cells.

7. A system comprising:
a vector-by-matrix multiplication array comprising non-volatile memory cells arranged into rows and columns; and
an input block comprising:
a global digital-to-analog converter to generate 2^{m} different analog voltages, where m is an integer; and
a plurality of row circuits, each row circuit comprising:
an address decoder to receive a row address and output an enable signal in response to the row address;
a row register storing activation data and outputting the activation data when the enable signal from the address decoder is asserted;
a selector to select and output one of the 2^{m} different analog voltages in response to the activation data;
a buffer to output a voltage received from the selector; and
a multiplexor to select a voltage received from the buffer or a voltage received from the selector and apply the selected voltage to a row in the vector-by-matrix multiplication array.

8. The system of claim 7, wherein the 2^{m} different analog voltages are spaced according to a linear function.

9. The system of claim 7, wherein the 2^{m} different analog voltages are spaced according to a logarithmic function.

10. The system of claim 7, wherein the global digital-to-analog converter comprises a voltage ladder to generate the 2^{m} different analog voltages.

11. The system of claim 7, wherein the non-volatile memory cells are stacked-gate flash memory cells.

12. The system of claim 7, wherein the non-volatile memory cells are split-gate flash memory cells.

13. A system comprising:
a vector-by-matrix multiplication array comprising non-volatile memory cells arranged into rows and columns; and
an input block configured based on a number of enabled rows.

14. The system of claim 13, wherein the input block comprises a row buffer to drive a line coupled to a row of non-volatile memory cells in the vector-by-matrix multiplication array.

15. The system of claim 14, wherein the input block disables the row buffer in a first mode to reduce power consumption.

16. The system of claim 15, wherein the input block enables the row buffer in a second mode to increase speed.

17. The system of claim 16, wherein the system selects the first mode or the second mode based on the number of enabled rows.

18. A method comprising:
configuring an input block based on a number of rows that are enabled in a vector-by-matrix multiplication array comprising non-volatile memory cells arranged into rows and columns; and
converting inputs into voltages applied to the enabled rows.

19. The method of claim 18, wherein the converting comprises converting the inputs from digital form into linear or logarithmic analog form.

20. The method of claim 18, wherein fewer rows are enabled to increase a speed of a read operation of the enabled rows.

21. The method of claim 18, wherein fewer rows are enabled to decrease power consumption.

22. A method comprising:
receiving differential bitline currents comprising a first current and a second current from a memory array;
adding a first bias current comprising one or more of a first timed bias current and a first fixed bias current to the first current to generate a third current;
adding a second bias current comprising one or more of a second timed bias current and a second fixed bias current to the second current to generate a fourth current; and
converting the third current and the fourth current into digital output bits.

23. The method of claim 22, wherein the first bias current is a first timed bias current and is applied during an initial period and disabled after the initial period.

24. The method of claim 23, wherein the second bias current is a first timed bias current and is applied during an initial period and disabled after the initial period.

25. The method of claim 22, wherein the converting comprises converting the third current and the fourth current into a first voltage and a second voltage and converting the first voltage and the second voltage into the digital output bits.

26. A method comprising:
receiving differential bitline currents comprising a first current and a second current from a memory array;
adding a first bias current comprising one or more of a first timed bias current and a first fixed bias current to the first current to generate a third current;
adding a second bias current comprising one or more of a second timed bias current and a second fixed current to the second current to generate a fourth current;
during a first period, converting the first fixed bias current and the second fixed bias current into a first set of digital bits; and
during a second period, converting the third current and the fourth current into a second set of digital bits.

27. The method of claim 26, wherein the first bias current is a first timed bias current applied during an initial period and disabled after the initial period.

28. The method of claim 27, wherein the second bias current is a second timed bias current applied during an initial period and disabled after the initial period.

29. The method of claim 26, comprising:
subtracting the first set of digital bits from the second set of digital bits to generate a third set of digital bits.
